(19) United States
(12) Patent Application Publication
(10) Pub. No.: US 2010/0116325 A1
(43) Pub. Date: May 13, 2010

(54) HIGH EFFICIENCY SOLAR PANEL AND SYSTEM

(76) Inventor: Mehrdad Nikoonahad, Menlo Park, CA (US)

Correspondence Address: DAVIS WRIGHT TREMAINE LLP - San Francisco, 505 MONTGOMERY STREET, SUITE 800, SAN FRANCISCO, CA, 94111, US

(21) Appl. No.: 12/616,732

(22) Filed: Nov. 11, 2009

Related U.S. Application Data
(60) Provisional application No. 61/268,252, filed on Jun. 10, 2009.
(60) Provisional application No. 61/198,979, filed on Nov. 12, 2008.

(51) Int. Cl. H01L 31/048; H01L 21/50

(52) U.S. Cl. 136/251; 438/64; 257/E21.499

(57) ABSTRACT

Disclosed is a photovoltaic solar panel with improved efficiency and the output of such panel can be AC. The panel can comprise a hermetically sealed space which comprises a first sheet, multiple energy conversion cells divided into groups, an access matrix and a second sheet. The access matrix can provide electrical access to individual or groups of energy conversion cells from locations outside the panel. Through the access matrix, a power module can be connected to individual energy conversion cells or groups of the cells to optimize the power generation efficiency. Also disclosed are method of making such a panel. Further disclosed is a photovoltaic power generation system comprising at least one such photovoltaic solar panel.

### CROSS REFERENCE TO RELATED APPLICATION

This application claims the benefit of U.S. Provisional Application No. 61/198,979, filed Nov. 12, 2008, entitled “High Efficiency Solar Panel and System,” and U.S. Provisional Application No. 61/268,252, filed Jun. 10, 2009, entitled “Solar Panel with Internal Bypass Diodes,” each of which is incorporated herein in its entirety by reference as if fully set forth herein.

### BACKGROUND

Our dependence on fossil fuel has led to an ever-increasing cost of energy. The green house gasses and the environmental impact of fossil fuels have in recent times created tremendous opportunity for alternative sources of energy, such as, for example, solar energy.

A photovoltaic solar panel comprising energy conversion cells can convert solar radiation incident on the panel to electricity.

FIG. 1 exemplifies an implementation of a photovoltaic solar power generation system. In this example, there are two parallel strings, each string comprising six photovoltaic solar panels (120) connected in series. Each panel includes multiple energy conversion cells (110). The overall DC power generated by the system (130) is fed to an inverter (140) which converts the DC power to AC power (150), which is in turn fed to the electric panel (160) and the meter (180) and eventually to the power grid (190) and appliances (170). In the system of FIG. 1, the energy conversion cells (110) within each panel (120) are connected in series to bring up the voltage; at the system level, the panels within each of the two strings are also connected in series.

A problem with a serial circuit is that the total output of a photovoltaic solar panel comprising multiple energy conversion cells in serial connection can be determined by the minimum current as offered from the weakest energy conversion cell. As used herein, a weak energy conversion cell can be an energy conversion cell which generates lower current than other energy conversion cells within a photovoltaic solar panel. The weak energy conversion cell can be due to the inferior intrinsic current generation capability of the cell compared to other cells in the panel, malfunction of the cells resulting from, such as, for example, physical damage to the cell, shading, or the like, or a combination thereof. In order to increase the total power output by a panel like that shown in FIG. 1, matching the current generation capability of the energy conversion cells within a panel can be a major consideration. Variation in both optical and electrical properties of the energy conversion cells can lead to a mismatch in current generation capability. The relevant properties can comprise, but not limit to, variations in cell thickness, the anti-reflection (AR) coating, doping concentration of the semiconductor, or the like, or a combination thereof. Even for energy conversion cells within a panel whose current generation capacities are well matched, partial shading by nearby trees, and/or cloud, and/or other structures can generate a time dependent variation in current generation capability of the individual energy conversion cells within the panel. Moreover, an individual malfunctioning energy conversion cell in serial connection with other normal cells within the panel can limit the total power output. The same effects can apply to a system comprising multiple panels in serial connection. A weak panel can affect the total power output of the multiple panels in serial connection. The weak panel can be due to, such as, for example, at least one weak energy conversion cell within the panel or partial shading on said weak panel.

The energy conversion cells in serially connected strings are nominally reverse biased. However, when there is one weak energy conversion cell in a string, the normal cells can become forward biased and feed power into the weak energy conversion cell where the power can be dissipated. Merely by way of example, for 10 cells connected in series, the current from the weak energy conversion cell, e.g., a shaded cell, can be approximately half of the current from the matched normal cells. The total voltage is equal and opposite in sign to the voltage across the weak energy conversion cell. A substantial portion of the power generated in the normal cells that can be dissipated in the weak energy conversion cell in the form of heat, leading to a “hot spot” in the panel. This can lead to overheating of the weak energy conversion cell, temperature increase in at least the neighboring cells, as well as damage to the whole panel. Descriptions about computer simulation and circuit design of photovoltaic systems can be found, for example, in Edenburn et al. (entitled “Computer Simulation of Photovoltaic Systems”, Twelfth IEEE Photovoltaic Specialists Conference, 1976, 667-672); Bobblo et al. (entitled “On the Series Resistance of Solar Cells”, Twelfth IEEE Photovoltaic Specialists Conference, 1976, 71-73); Gonzalez and Weaver (entitled “Circuit Design Considerations for Photovoltaic Modules and Systems”, Fourteenth IEEE Photovoltaic Specialists Conference, 1980, 528-535); and Gonzalez et al. (entitled “Determination of Hot-Spot Susceptibility of Multistring Photovoltaic Modules in a Central-Station Application,” Seventeenth IEEE Photovoltaic Specialists Conference, 1984, 668-675), each of which is incorporated herein by reference.

This problem associated with a serial circuit can be ameliorated partially using bypass diodes. FIG. 2 shows an exemplary arrangement for multiple energy conversion cells within a panel. The panel can comprise 54 energy conversion cells (210) in serial connection. The 54 energy conversion cells (210) can be divided into three strings, String I (250), String II (260) and String III (270). Each string can include 18 energy conversion cells (210) in serial connection and a bypass diode (220). One weak energy conversion cell can affect the power generation of the string to which it belongs, but not the power generation of the other two strings. Merely by way of example, a weak energy conversion cell (210′) in String II can affect the power generation of String II (260), but not the power generation of String I (250) or String III (270).

However, it is difficult to implement more bypass diodes to further ameliorate the effect of individual weak energy conversion cell(s) on energy generation of a string of energy conversion cells electrically connected to the weak energy conversion cell(s) in series. It can be because it is difficult to access individual energy conversion cells or a group comprising a small number of electrically connected energy conversion cells which are sealed within the panel.

### SUMMARY

In one embodiment, a photovoltaic solar panel is proposed, which employs energy conversion cells arranged in a plurality of groups in a hermetically sealed space. An access matrix is provided comprising a plurality of electrical conductors that are electrically connected to the groups and that extend out of said hermetically sealed space to provide electrical access to the groups from locations outside the panel. Exemplary methods of fabricating the access matrix are described.

In one implementation of this embodiment, the hermetically sealed space is provided by means of a first sheet and a second sheet adjacent to each other defining a space in between the two sheets. At least one lamination layer in said space is used to provide hermetical sealing for said energy conversion cells in the space. Other means for hermetically sealing the space can also be used instead. The first sheet is substantially transparent to solar radiation incident on the panel.

In some embodiments, a photovoltaic solar panel can include photovoltaic cells, high voltage energy conversion cells, or the like, or a combination thereof. A high voltage energy conversion cell can include multiple sub-cells. A high voltage energy conversion cell can generate power of high voltage which can be substantially proportional to the number of sub-cells the it includes.

In some embodiments, a photovoltaic solar panel can generate alternating current (AC) power. A photovoltaic solar panel can include a power module. A power module can be located on an external surface of the panel.

Some embodiments can include methods of manufacturing a power solar panel which can include an access matrix.

In other embodiments, a photovoltaic power generation system can comprise at least one photovoltaic solar panel described herein.

### BRIEF DESCRIPTION OF THE DRAWINGS

FIG. 1 illustrates a photovoltaic power generation system comprising multiple photovoltaic solar panels in serial connection.

FIG. 2 illustrates a photovoltaic solar panel comprising multiple energy conversion cells and bypass diodes.

FIG. 3A illustrates an exemplary embodiment of an access matrix from a cross-sectional view.

FIG. 3B illustrates an exemplary embodiment of an access matrix from a cross-sectional view.

FIG. 3C illustrates an exemplary embodiment of an access matrix from a cross-sectional view.

FIG. 3D illustrates an exemplary embodiment of an access matrix from a cross-sectional view.

FIG. 3E illustrates an exemplary embodiment of an access matrix from a cross-sectional view.

FIG. 4A illustrates an exemplary photovoltaic solar panel with an access matrix and a power module.

FIG. 4A-1 illustrates constituent layers of the exemplary photovoltaic solar panel shown in FIG. 4A.

FIG. 4B illustrates an exemplary photovoltaic solar panel with an access matrix and a power module.

FIG. 4B-1 illustrates constituent layers of the exemplary photovoltaic solar panel shown in FIG. 4B.

FIG. 5 illustrates an exemplary photovoltaic solar panel comprising an access matrix from a cross-sectional view.

FIG. 6A illustrates an exemplary energy conversion cell with dedicated electronics from a cross-sectional view.

FIG. 6B illustrates an exemplary energy conversion cell with a dedicated bypass diode from a cross-sectional view.

FIG. 7A illustrates two energy conversion cells as shown in FIG. 6A serially connected to form a string by metal tapes from a cross-sectional view.

FIG. 7B illustrates two energy conversion cell as shown in FIG. 6A are serially connected to form a string by metal pins from a cross-sectional view.

FIG. 8 illustrates packaging the energy conversion cell string as shown in FIG. 6A into a photovoltaic solar panel from a cross-sectional view.

FIG. 9A illustrates a group of energy conversion cells with dedicated electronics connected to access matrix.

FIG. 9B illustrates multiple groups of energy conversion cells in serial connection connected to access matrix, wherein each group includes dedicated electronics.

FIG. 9C illustrates multiple groups of energy conversion cells in parallel connection and connected to access matrix.

FIG. 9D illustrates multiple groups of energy conversion cells connected to an access matrix.

FIG. 9E illustrates multiple groups of energy conversion cells connected to sub-matrices of an access matrix.

FIG. 10A illustrates a block diagram of an exemplary power module.

FIG. 10B illustrates a block diagram of an exemplary power module.

FIG. 10C illustrates a block diagram of an exemplary AC panel comprising a photovoltaic solar panel and a power module.

FIG. 11 illustrates a block diagram of an exemplary AC panel comprising groups of energy conversion cells and a power module.

FIG. 12A illustrates an exemplary embodiment of three energy conversion cells in serial connection from a cross-sectional view.

FIG. 12B including FIG. 12B-1, FIG. 12B-2 and FIG. 12B-3 illustrates an exemplary high voltage cell.

FIG. 13 illustrates an exemplary method of photovoltaic solar panel fabrication.

FIG. 14 illustrates a photovoltaic power generation system comprising multiple AC panels, wherein each photovoltaic solar panel comprises a power module.

FIG. 15A illustrate an exemplary power module with electrical connection components through which an AC panel can output the AC generated by the panel.

FIG. 15B illustrates an exemplary connection of the AC panels through the power modules with electrical connection components exemplified in FIG. 15A.

FIG. 15C illustrates an exemplary connection of the AC panels through the power modules with electrical connection components exemplified in FIG. 15A.

### DETAILED DESCRIPTION

The instant application is generally related to a photovoltaic solar panel and a system thereof with improved efficiency.

A photovoltaic solar panel can comprise a first sheet and a second sheet adjacent to each other defining a space in between the two sheets, energy conversion cells arranged in a plurality of groups in said space, and an access matrix in said space. Said space between and including the first sheet and the second sheet can be hermetically sealed to enclose said energy conversion calls therein. The access matrix can comprise a plurality of electrical conductors that are electrically connected to the groups of energy conversion cells and extend out of said space to provide electrical access to the groups from locations outside the panel.

A photovoltaic solar panel can comprise a first sheet. The first sheet can be substantially transparent to solar radiation incident on the panel. As used herein, substantially indicates ±20% variation of the value it describes, unless otherwise stated. Merely by way of example, the first sheet can transmit at least about 50%, or at least about 60%, or at least about 70%, or at least about 80%, or at least about 90%, or at least about 95% of the solar radiation incident on the panel to the energy conversion cells. As used herein, about indicates ±20% variation of the value it describes, unless otherwise stated. The first sheet can comprise at least one material selected from glass, polyvinyl fluoride (PVF), polyester, ethylene vinyl acetate (EVA), Mylar, plastic, polyethylene, Kapton, polyimide, and polydinofluoride. The thickness of the first sheet can be from about 1 micrometer to about 50 centimeters, or from about 10 micrometers to about 10 centimeters, or from about 100 micrometers to about 1 centimeter, or from about 1 millimeter to about 8 millimeters, or from about 2 millimeters to about 5 millimeters. The first sheet can comprise an anti-reflection (AR) coating. The AR coating can comprise a dielectric stack and/or at least one material selected from fluoropolymers, zinc oxide, titanium dioxide, silicon dioxide, indium tin oxide, silicon nitride, magnesium fluoride and the like. Merely by way of example, the first sheet can comprise a tempered and textured glass with low iron content with a treatment as described in Amrani A. K. et al, (“Solar Module Fabrication”, International Journal of Photoenergy Volume 2007, Article ID 27610) which is incorporated herein by reference.

A photovoltaic solar panel can comprise a second sheet. The second sheet can comprise at least one material selected from glass, polyvinyl fluoride, polyester, ethylene vinyl acetate, Mylar, plastic, polyethylene, Kapton, polyimide, and polydinofluoride. The thickness of the second sheet can be from about 1 micrometer to about 50 centimeters, or from about 10 micrometers to about 10 centimeters, or from about 100 micrometers to about 1 centimeter, or from about 1 millimeter to about 8 millimeters, or from about 2 millimeters to about 5 millimeters. The second sheet can transmit less than about 50%, or less than about 40%, or less than about 30%, or less than about 20%, or less than about 10%, or less than about 5% of the solar radiation which reaches the second sheet. The second sheet can comprise a reflective coating such that the solar radiation travelling through the energy conversion cells can be reflected by the coating generally back into the cells. The reflective coating can comprise a dielectric stack and/or at least one material selected from, for example, Au, Ag, Cu, Al, Mg, Ni, Fe, Cr, Mo, W, Ti, Co, Ta, Nb, Zr, stainless steel, and the like. The reflective coating can comprise a dielectric stack and/or at least one alloy comprising at least one element selected from, for example, Au, Ag, Cu, Al, Mg, Ni, Fe, Cr, Mo, W, Ti, Co, Ta, Nb and Zr.

The second sheet can comprise the same material and/or the same thickness as the first sheet. The second sheet can comprise different material or different thickness than the first sheet. Merely by way of example, the second sheet can comprise the same material as the first sheet, but with a different treatment than the first sheet such that the second sheet can be less transmissive to solar radiation than the first sheet. A treatment can comprise, for example, a mechanical or chemical surface treatment, a modification (e.g., increase or reduction) in element content of the material, or the like, or a combination thereof. Furthermore the second sheet can be designed in such a way to enhance the removal of heat from the space between the first sheet and the second sheet. Said removal can be both by means of conduction and radiation.

A photovoltaic solar panel can comprise at least one energy conversion cell. The energy conversion cells can be, such as, for example, a photovoltaic cell (also known as solar cell). Photovoltaic cells can be made from individual wafers of monocrystalline or multicrystalline (also known as polycrystalline) silicon. Photovoltaic cells can be manufactured by thin film technologies. Photovoltaic cells can be made by depositing one or more thin layers (thin film) of photovoltaic material on a substrate, such as, for example, the first sheet or second sheet herein described, and then defining individual cells by laser scribing. The substrate can comprise at least one material selected from glass, plastic or metal. The photovoltaic material can comprise cadmium telluride (CdTe), copper indium gallium selenide (CIGS), amorphous silicon (a-Si), or tandem junction silicon in which a layer of amorphous silicon and poly-silicon are deposited atop each other. Photovoltaic cells manufactured based on thin film technologies can comprise, such as, for example, cadmium telluride (CdTe), copper indium gallium selenide (GIGS), dye-sensitized solar cell (DSC), organic solar cell such as Power Plastic® materials produced Konarka Technologies, Inc (www.konarka.com), thin-film silicon (TF-Si), or amorphous silicon (a-Si). A person of ordinary skill in the relevant art will recognize that the technology described herein is applicable to various types of energy conversion cells, including those exemplified above.

A photovoltaic solar panel can comprise multiple energy conversion cells. Within a photovoltaic solar panel, energy conversion cells can be distributed across a substantially two-dimensional plane between and adjacent to the first sheet and the second sheet. As used herein, “two-dimensional plane” can refer to a plane which is substantially parallel to the first sheet and/or the second sheet. Each energy conversion cell can have a positive polarity and a negative polarity, which can be on one side or opposite sides of the cell. As used herein, a side of an energy conversion cell can refer to an outer surface of the cell which is substantially parallel to the two-dimensional plane of the photovoltaic solar panel. A top side can refer to the side which is closer to the first sheet; and a bottom side can refer to the side which is closer to the second sheet. The energy conversion cells can be connected to each other by a serial connection, or a parallel connection, or a combination thereof. The energy conversion cells within a photovoltaic solar panel can be divided into a plurality of groups, such as, for example, at least two groups, or at least three groups, or at least four groups, or at least five groups, or at lest six groups, or at least seven groups, or at least eight groups, or at least nine groups, or at least ten groups, or at least eleven groups, or at least twelve group, or more. As used herein, a group can refer to a certain number of energy conversion cells. A group can comprise at least one energy conversion cell, or at least two cells, or at least three cells, or at least four cells, or at least five cells, or at least six cells, or at least seven cells, or at least eight cells, or at least ten cells, or at least twenty cells, or at least fifty cells, or more than fifty cells. A group can comprise fewer than twenty energy conversion cells, or fewer than fifteen cells, or fewer than twelve cells, or fewer than ten cells, or fewer than eight cells, or fewer than six cells, or fewer than five cells, or fewer than four cells, or fewer than three cells, or fewer than two cells. All groups within a photovoltaic solar panel can comprise the same number of energy conversion cells. At least one group can comprise a different number of energy conversion cells than other groups within the photovoltaic solar panel. If a group comprises more than one energy conversion cell, the cells within the group can be electrically connected to each other by at least one serial connection, or by at least one parallel connection, or a combination thereof. Each group can comprise at least a positive polarity terminal and at least a negative polarity terminal through which the group can be electrically connected to another group, and/or an access matrix, and/or to an electrical device. The plurality of groups within a photovoltaic solar panel can be connected by at least one serial connection, or at least a parallel connection, or a combination thereof.

It is understood that the multiple energy conversion cells can be distributed across a surface or surfaces other than a substantially two-dimensional plane. Merely by way of example, the energy conversion cells can be distributed on the external surfaces of a three-dimensional structure, e.g., a pyramid. The description of the instant application is primarily based on the situations in which the energy conversion cells are distributed across a substantially two-dimensionally plane merely for the purpose of illustration and convenience, and is not intended to limit the scope of the application. For example, for the case of Power Plastic® organic solar cells, such cells can be wrapped around a substantially three dimensional structure.

A photovoltaic solar panel can comprise an access matrix. The access matrix can provide access to individual energy conversion cells and/or groups of energy conversion cells. The access can comprise, such as, for example, mechanical access and/or electrical access. Merely by way of example, electrical access can provide for making electrical connections to individual cells or groups of cells within the panel; mechanical access can provide appropriate cavities for placement and encapsulation of electronic components, such as, for example, low profile diodes, super barrier rectifiers, DC-DC converters, temperature sensors and/or other dedicated electronics to provide specific electronic functionality.

The access matrix can be located between the first sheet and the energy conversion cells, and/or between the energy conversion cells and the second sheet. The access matrix can comprise two or more sub-matrices. The two or more sub-matrices can be located next to each other or separately. Merely by way of example, the access matrix can comprise two sub-matrices, one between the first sheet and the energy conversion cells, and the other between the energy conversion cells and the second sheet. As another example, the access matrix can comprise two or more sub-matrices on a substantially two-dimensional plane which is substantially parallel to the plane where the energy conversion cells locate, wherein one sub-matrix can be electrically connected to the positive polarity of the individual energy conversion cells and/or the groups of cells, and the other sub-matrix can be electrically connected to the negative polarity of the individual energy conversion cells and/or groups of cells. Alternatively, one sub-matrix of the access can provide connectivity at one side of the panel to one group of cells and the other sub-matrix or sub-matrices can provide connectivity at the other end of the panel to other group or groups of cells. The access matrix can transmit at least about 50%, or at least about 60%, or at least about 70%, or at least about 80%, or at least about 90%, or at least about 95% of the solar radiation incident on the panel to the energy conversion cells. The access matrix can transmit at least about 50%, or at least about 60%, or at least about 70%, or at least about 80%, or at least about 90%, or at least about 95% of the solar radiation reaching the access matrix within the panel. If an access matrix, or a sub-matrix in the case when the access matrix comprises two or more sub-matrices, is located between the energy conversion cells and the second sheet, the access matrix or the sub-matrix can comprise a reflective coating such that solar radiation reaching the access matrix (or the sub-matrix) can be reflected by the coating generally back into the cells. The reflective coating can comprise any suitable dielectric stack and/or at least one material selected from, for example, Au, Ag, Cu, Al, Mg, Ni, Fe, Cr, Mo, W, Ti, Co, Ta, Nb, Zr, stainless steel, and the like. The reflective coating can comprise any suitable dielectric stack and/or at least one alloy comprising at least one element selected from, for example, Au, Ag, Cu, Al, Mg, Ni, Fe, Cr, Mo, W, Ti, Co, Ta, Nb and Zr.

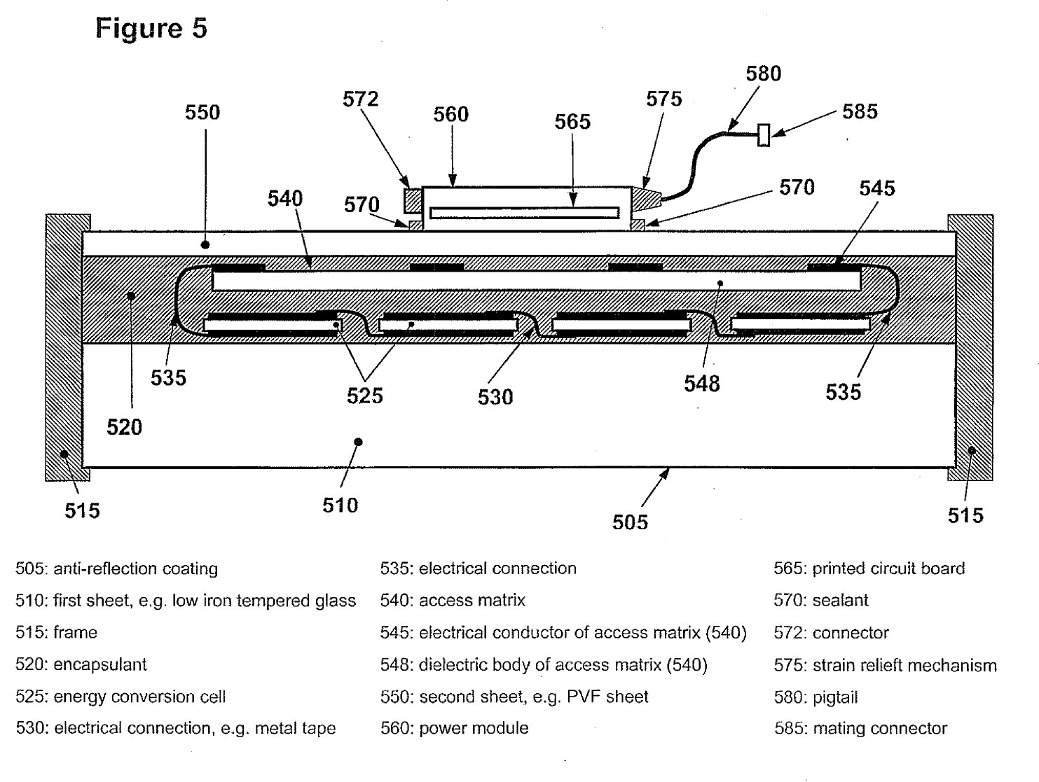

The access matrix can comprise one or more dielectric bodies, such as that of an insulating plating of a printed circuit board (PCB). A dielectric body can form an insulating plane. The thickness of the dielectric body can be from about 1 nanometer to about 50 centimeters, or from about 1 micrometer to about 10 centimeters, or from about 10 micrometers to about 1 centimeter, or from about 50 micrometers to about 1 millimeter, or from about 100 micrometers to about 500 micrometers. The dielectric body can comprise at least one layer of material. The material can be chosen based on various considerations. Merely by way of example, the considerations can comprise a high thermal conductivity, durability, low permeability for vapors (e.g., water vapor), chemical compatibility and adhesiveness to the neighboring materials, compatibility to a production process (e.g. a thermo-compression lamination process), fire retardation, and low temperature coefficient of expansion and temperature coefficient of expansion compatible with the neighboring materials, and the like. A high thermal conductivity can assist in controlling the temperature of the energy conversion cells by facilitating heat dissipation. For example, an access matrix with high thermal conductivity can transfer the heat from the back of the panel to the metallic frame where the heat can be dissipated and as such a metallic frame can act as a heat sink. An exemplary metallic frame is shown as 515 in FIG. 5. The second sheet can be provided with a back cavity that acts as a heat exchanger and cold water can be made to flow into this cavity and warmer water out, thereby removing the heat from the back of the panel. Within the cavity the water flow can be arranged to follow a serpentine path to increase contact with the back of the panel. This can be beneficial to the energy conversion efficiency of a cell because there can be a drop of about 0.3-0.5% in power output per degree Celsius increase in cell temperature. The material for the dielectric body of access matrix can comprise at least one material selected from polyvinyl fluoride (PVF), polyethylene terephthalate, polyimide, flame retardant 4, (FR-4). The dielectric body can comprise PVF, also known as Tedlar, which is a thermoplastic fluoropolymer with repeating vinyl fluoride units. PVF can have low permeability for vapors, low flammability, and good resistance to weathering, staining and most chemicals. It is available as a film in a variety of colors and/or formulations for various end uses, and as a resin for specialty coating. It can be purchased from DuPont. The dielectric body of an access matrix can comprise Mylar or biaxially-oriented polyethylene terephthalate (boPET). The dielectric body can comprise polyimide which can comprise various engineered impurities. Polyimide can be lightweight, flexible, and resistant to heat and chemicals. Polyimide is known under the trade names, such as, for example, Kapton, Apical, UPILEX, VTEC Pl, Norton TH, Kaptrex and Pyralux. The dielectric body of an access matrix can comprise FR-4, which can also be used to make a printed circuit board (PCB). Merely by way of example, a dielectric body of the access matrix can comprise one or more layers of polyethylene or polyester. As another example, the dielectric body of an access matrix can comprise a layer of material with high thermal conductivity sandwiched between two layers of materials with good adhesion properties.

If the access matrix comprises two or more sub-matrices, any one of the sub-matrices can comprise a dielectric body. In some embodiments, the dielectric body(s) of the access matrix can coincide with the first sheet, and/or the second sheet, and/or any intervening layers between the first sheet and the second sheet.

The access matrix can comprise a plurality of electrical conductors. The electrical conductors can be electrically connected to the energy conversion cells within a group, and/or different groups within a photovoltaic solar panel. The electrical conductors can extend out of the space defined by the energy conversion cells to provide electrical access to individual energy conversion cells and/or groups of the cells from locations outside said space and/or the panel. The electrical conductors can deliver power generated by individual energy conversion cells and/or groups of the cells to a location outside the space and/or the panel. The electrical conductors can electrically connect individual energy conversion cells and/or groups of the cells to other electrical devices at a location outside the space and/or the panel.

An electrical conductor can comprise at least one electrically conductive material of low resistance. For example, the resistivity can be less than about 10000 ohm·mm, or less than about 1000 ohm·mm, or less than about 500 ohm·mm, or less than about 100 ohm·mm, or less than about 50 ohm·mm, or less than about 1 ohm·mm, or less than 10⁻³ ohm·mm. The electrically conductive material can comprise one selected from copper, aluminum, tin, tin coated copper, silver, steel, stainless steel, brass and bronze, or the like, or a combination thereof, such as for example tin coated copper tape. For example, and without any limitation, the copper tape can be from about 2 mm to about 5 mm wide and from about 50 micrometers to about 300 micrometers thick covered with a tin layer of about 10 micrometers to about 30 micrometers. The electrical conductor can have a cross-sectional shape selected from rectangular, circular, oval, square, or the like. The electrical conductor can comprise an electrically conductive tape, electrically conductive ink, an electrically conductive track, an electrically conductive wire, or the like.

The electrical conductor of the access matrix can be arranged in various ways. The electrical conductor, such as, for example, a conductive track, can be formed using self adhesive tapes, such as, for example, those manufactured by 3M. The self adhesive tapes can be electrically conductive. Merely by way of example, the self adhesive tapes can comprise metal tapes. The self adhesive tapes can be non-conductive but can adhere conductive tracks to the dielectric body. The electrical conductor can be formed by printing electrically conductive ink onto the surface of the dielectric body. The electrical conductor can be formed by surface coating the dielectric body with an electrically conductive material, such as, for example, a metal, and then treating the coated surface in a process similar to lithography in order to etch off the unwanted electrically conductive material. The metal can comprise, for example, copper, aluminum, tin, tin coated copper, silver, steel, stainless steel, brass and bronze, or the like, or a combination thereof. The electrical conductor can be embedded in the dielectric body of the access matrix with at least a portion of the electrical conductor exposed. The exposed portion of the electrical conductor can include, such as, for example, an exposed electrically conductive surface of the electrical conductor, dangling ends extending out of the dielectric body, or the like, or a combination thereof. Merely by way of example, electrically conductive wires can be placed in a mold, the mold can be filled with resin, and then the resin can be cured. The electrically conductive wire can include dangling ends that extend out of the dielectric body so that the electrically conductive wire embedded within the dielectric body can be electrically connected to an individual energy conversion cell and/or a group of cells by soldering the dangling ends to the individual energy conversion cell and/or a group of cells. The solder can be a lead free solder available from Kester (www.kester.com). The soldering flux can be a no-solids, no-clean flux such as #979T or #951 also available from Kester. In some embodiments, there can be an additional layer of material between the energy conversion cells and the access matrix, wherein at least a portion of the electrical conductor can penetrate the additional layer in order to be electrically connected with an individual cell and/or a group of cells.

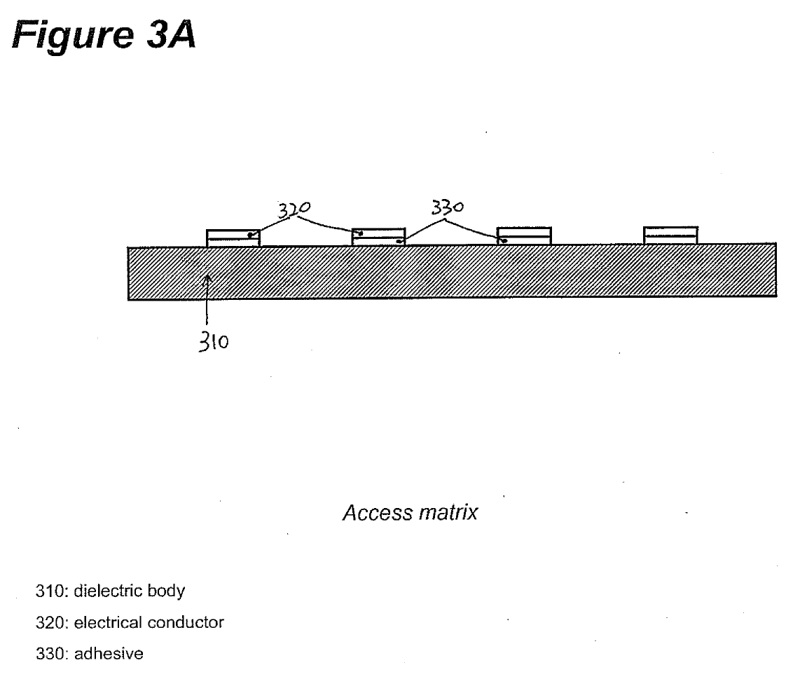

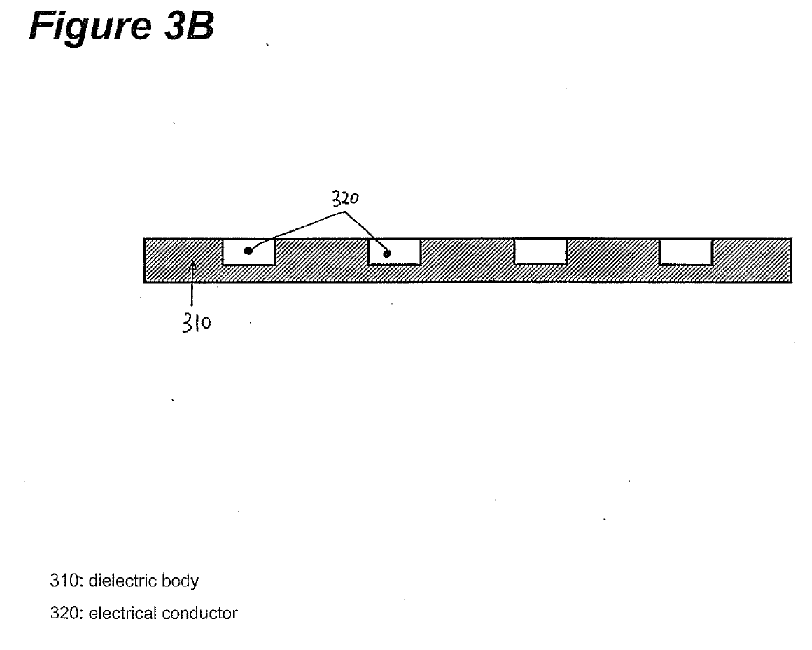

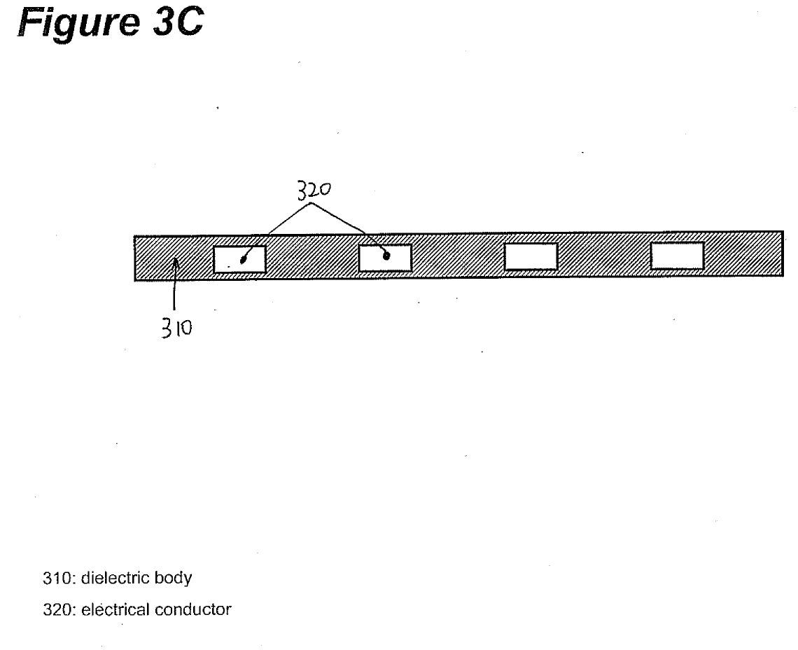

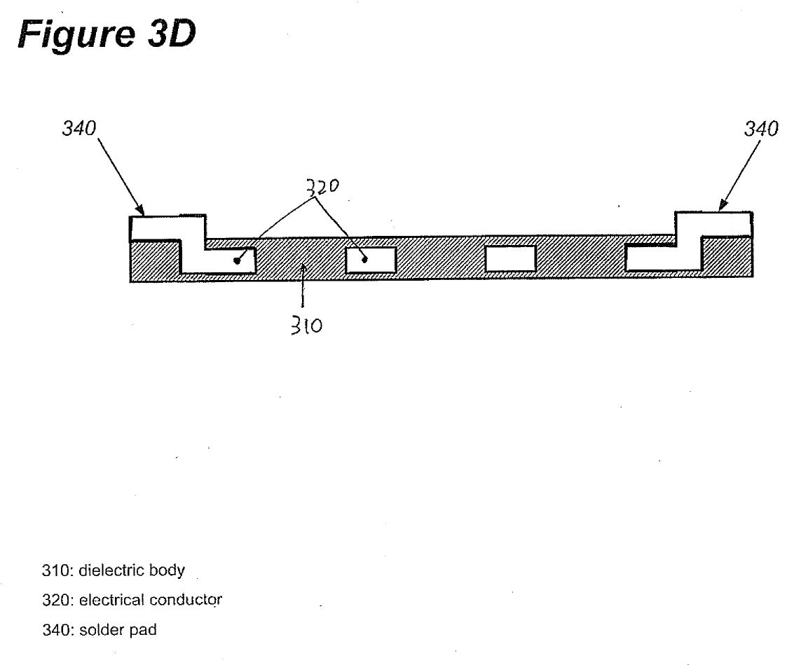

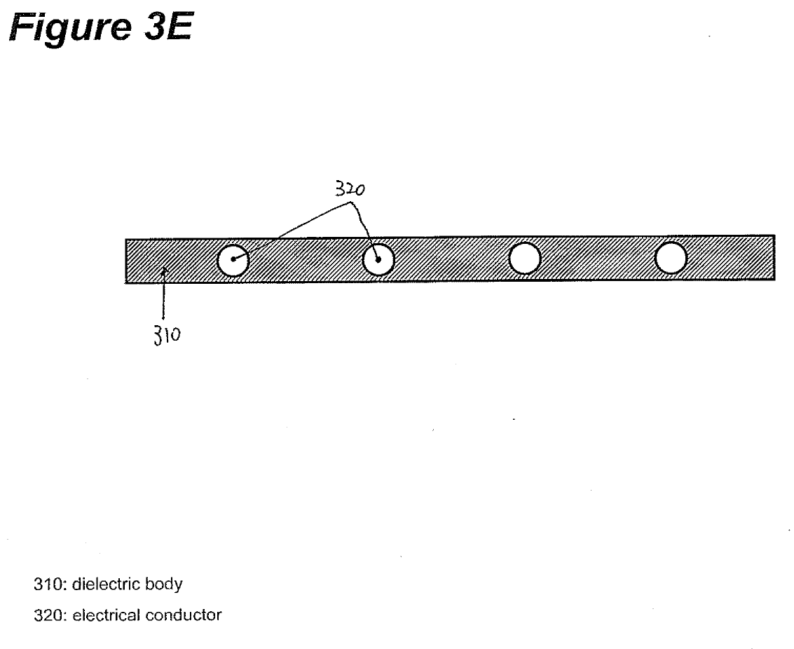

FIG. 3A to FIG. 3E illustrate exemplary arrangements of the access matrix from a cross-sectional view. In FIG. 3A, the access matrix can include a dielectric body (310), electrical conductors (320) and adhesive (330). The adhesive (330) can adhere to an electrical conductor (320) to the surface of the dielectric body (310). An electrical conductor can be in direct contact with and electrically connected to an individual energy conversion cell and/or a group of cells. In FIG. 3B, the access matrix can include a dielectric body (310) and electrical conductors (320). An electrical conductor (320) can be embedded in the dielectric body (310), wherein at least a portion of the electrical conductor, such as, for example, an electrically conductive surface, can be exposed, such that the electrical conductor can be in direct contact with and electrically connected to an individual energy conversion cell and/or a group of cells. In FIG. 3C, the access matrix can include a dielectric body (310) and electrical conductors (320). An electrical conductor (320) can be embedded in the dielectric body (310). The electrical conductor can include, such as, for example, dangling ends which extend out of the dielectric body (310) and can electrically connect to an individual energy conversion cell and/or a group of cells by soldering the dangling ends to the individual energy conversion cell and/or a group of cells. The solder can be a lead free solder available from Kester (www.kester.com). The soldering flux can be a no-solids, no-clean flux such as #979T or #951 also available from Kester. Each of the electrical conductors can have a rectangular cross-sectional shape. In FIG. 3D, the access matrix can include a dielectric body (310), electrical conductors (320) and solder pads (340). An electrical conductor (320) can be embedded in the dielectric body (310). The solder pad (340) can penetrate the dielectric body (310). The electrical conductor (320) can be electrically connect to an individual energy conversion cell and/or a group of cells through the solder pads (340). Each of the electrical conductors can have a rectangular cross-sectional shape. In FIG. 3E, the access matrix includes a dielectric body (310) and electrical conductors (320). An electrical conductor (320) can be embedded in the dielectric body (310). The electrical conductor can include, such as, for example, dangling ends which extend out of the dielectric body (310) and can electrically connects to an individual energy conversion cell and/or a group of cells. Each of the electrical conductors can have a circular cross-sectional shape.

An electrical conductor can extend beyond the space defined by the first sheet and the second sheet to locations outside the hermetically sealed space and/or the photovoltaic solar panel.

The photovoltaic solar panel can comprise a lamination layer in the space defined by the first sheet and the second sheet. The lamination layer can provide hermetical sealing for the energy conversion cells in the space. The lamination layer can comprise the first sheet, the energy conversion cells, the access matrix and the second sheet. The lamination layer can further comprise at least a layer of encapsulant. The encapsulant can comprise, such as, for example, ethylene-vinyl acetate (EVA). The lamination layer can comprise at least two layers of encapsulant, one on each side of the energy conversion cells. The access matrix can provide electrical access to individual energy conversion cells and/or groups of energy conversion cells from locations outside the lamination layer or outside the panel.

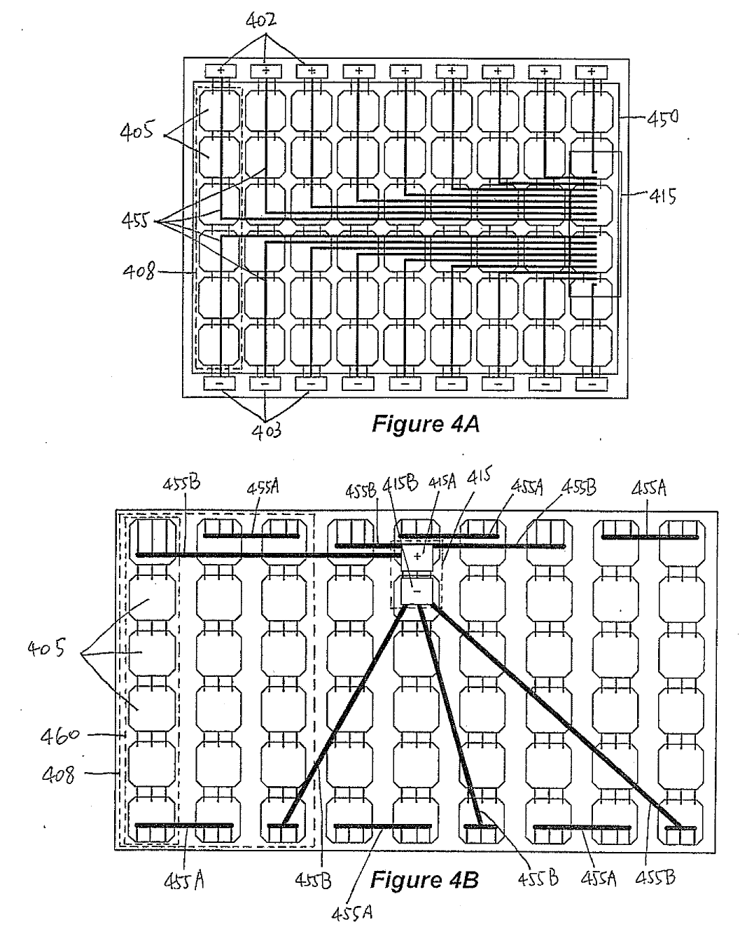

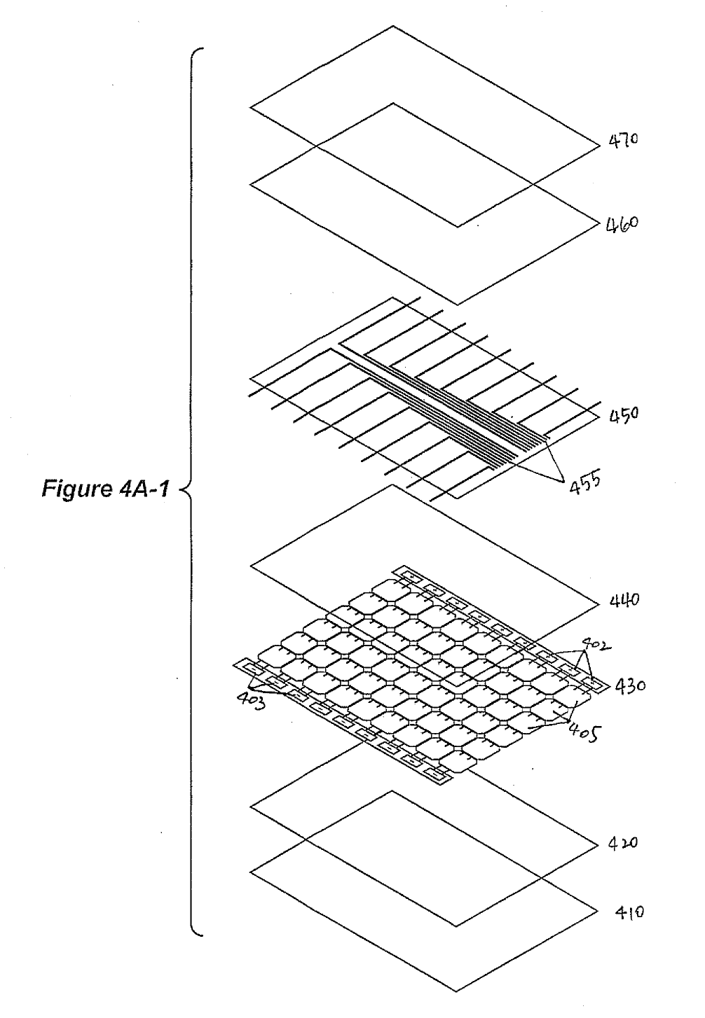

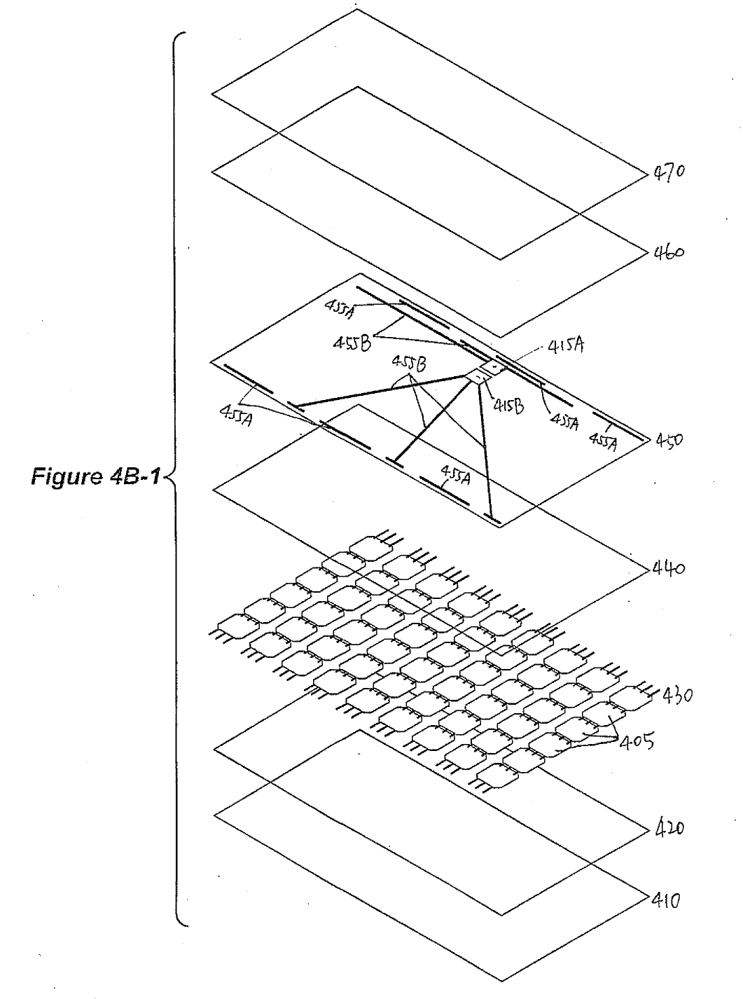

FIG. 4A illustrates one exemplary photovoltaic solar panel with a power module (415), wherein the energy conversion cells (405) in the panel can be electrically connected through an access matrix (450). The panel can comprise, without any limitation, 54 energy conversion cells (405). The 54 energy conversion cells (405) can be divided into 9 groups (408). Energy conversion cells (405) within each group (408) can be internally connected in series. Each group can comprise a positive polarity (402) and a negative polarity (403). The positive polarity (402) and the negative polarity (403) of each group (408) can be brought, via the electrical conductors (455) of the access matrix (450), to the power module (415) (illustrated as the rectangular box on the right). The power module (415) can be mounted, or be permanently attached on the back of the panel.

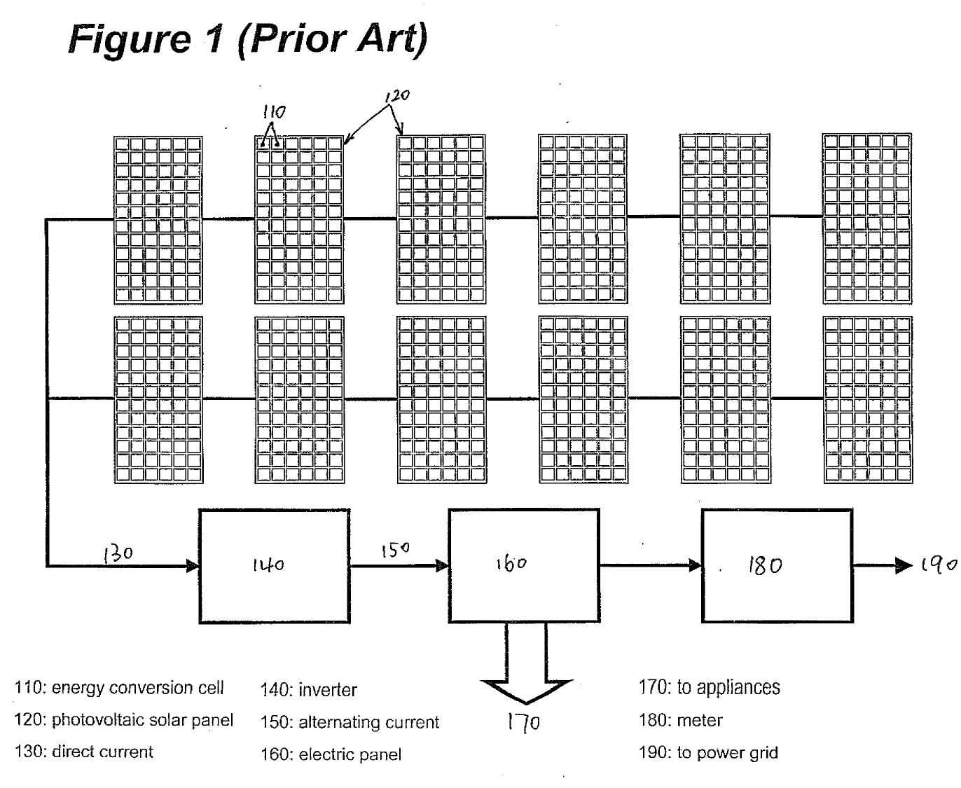

FIG. 4A-1 illustrates constituent layers of the exemplary photovoltaic solar panel shown in FIG. 4A. The same numbers in FIG. 4B-1 illustrate the same parts as in FIG. 4A. The exemplary photovoltaic solar panel can comprise a first sheet (410) comprising, e.g., glass or more preferably low-iron tempered glass, a first layer of encapsulant (420) comprising, e.g. EVA, energy conversion cells (430) distributed in an essentially two-dimensional plane, a second layer of encapsulant (440) comprising, e.g. EVA, an access matrix (450) with electrical conductors (455), a third layer of encapsulant (460) comprising, e.g. EVA, and a second sheet (470) comprising, e.g. PVF. The first sheet (410) of glass, or more preferably low-iron tempered glass, can comprise an anti-reflection (AR) coating and be tempered. The access matrix (450) can provide electrical access to the individual energy conversion cells (405) or groups (408) of electrically connected cells (405) within the lamination layer from locations outside the panel. There can be at least one power module (415) located outside the panel. The power module (415) can be electrically connected to individual energy conversion cells (405) or groups (408) within the panel through the electrical conductors (455) of the access matrix (450).

FIG. 4B illustrates another exemplary photovoltaic solar panel with a power module (415), wherein the energy conversion cells (405) in the panel can be electrically connected through an access matrix (450). The same numbers in FIG. 4B-1 illustrate the same parts as in FIG. 4A and FIG. 4A-1. The panel, without any limitation, can comprise 54 energy conversion cells (405). The 54 energy conversion cells (405) can be divided into three groups (408), wherein each group can comprise 18 cells (405). Each 6 cells are connected in series to form a sub-group (460); and three sub-groups (460) in each of the three groups (408) are connected in series through the electrical conductors (455A) of the access matrix (450) to form such a group of 18 cells (408). The three groups (408) can be connected in parallel via the electrical conductors (455B) of the access matrix (450) and the power module (415). In this case two electrical conductors can come out of power module (415) of the panel from the positive polarity terminal (415A) and the negative polarity terminal (415B) of the power module (415).

FIG. 4B-1 illustrates constituent layers of the exemplary photovoltaic solar panel shown in FIG. 4B. The same numbers in FIG. 4B-1 illustrate the same parts as in FIG. 4A, FIG. 4A-1 and FIG. 4B. The exemplary photovoltaic solar panel can comprise a first sheet (410) comprising, e.g., glass, or more preferably low-iron tempered glass, a first layer of encapsulant (420) comprising, e.g. EVA, energy conversion cells (430) distributed in an essentially two-dimensional plane, a second layer of encapsulant (440) comprising, e.g. EVA, an access matrix (450) with electrical conductors (455), a third layer of encapsulant (460) comprising, e.g. EVA, and a second sheet (470) comprising, e.g. PVF or Tedlar. The first sheet (410) of glass, or more preferably low-iron tempered glass, can comprise an anti-reflection (AR) coating. The access matrix (450) can provide electrical access to the individual energy conversion cells (405) or groups (408) of electrically connected cells (405) within the lamination layer from locations outside the panel. There can be at least one power module (415) located outside the panel. The power module (415) can be electrically connected to individual energy conversion cells (405) or groups (408) within the panel through the electrical conductors (455) of the access matrix (450).

It is understood that FIG. 4A and FIG. 4B are for illustration purposes only and are not intended to limit the scope of the application. It is clear that numerous connection topologies can be realized by the access matrix.

FIG. 5 shows an exemplary photovoltaic solar panel from a cross-sectional view. 505 illustrates an anti-reflection coating on the first sheet (510); 510 illustrates the first sheet; 515 illustrates the frame; 520 illustrates encapsulant; 525 illustrates the energy conversion cells; 530 illustrates the electrical connection between energy conversion cells; 535 illustrates an electrical connection which connects the energy conversion cells to the electrical conductors (545) of the access matrix (540); 540 illustrates the access matrix; 545 illustrates the electrical conductor of the access matrix (540); 548 illustrates the dielectric body of the access matrix (540); 550 illustrates the second sheet; 560 illustrates the power module; 565 illustrates the printed circuit board (PCB) within the power module (560); 570 illustrates the sealant; 572 illustrates the connector; 575 illustrates the strain relief mechanism; 580 illustrates the pigtail; and 585 illustrates the mating connector. The first sheet (510) can be glass, or more preferably low-iron tempered glass. The second sheet (550) can be a sheet of PVF or Tedlar. The pigtail (580) is a wire that can deliver AC out of the panel. This wire can be a multi-conductor wire so that it can accommodate single-phase, two-phase, split-phase and three-phase transmission. The hermetically sealed space can comprise the sealed space between the first sheet (510) and the second sheet (550), and can include the first sheet (510), the encapsulant (520), the energy conversion cells (525) distributed across a substantially two-dimensional plane and connected to each other through the electrical connection (530), the access matrix (540) with a dielectric body (548) and electrical conductors (545) and connected to the energy conversion cells or groups of cells through the electrical connection (535), and the second sheet (550). The frame (515) can include, such as, for example, aluminum which can be connected to AC ground for safety. The panel can include at least one layer of encapsulant, wherein the at least one layer of encapsulant can be located between the first sheet and the energy conversion cells, and/or between the energy conversion cells and the access matrix, and/or between the access matrix and the second sheet. The power module (560) can include electronic components which can invert DC power generated by the energy conversion cells within the panel to AC power. The power module (560) can include components which can sample and/or modify the DC or AC to generate power, e.g., AC power, suitable to be delivered to, such as, for example, appliances and/or power grids. The power module (560) can include components which can monitor the performance of the panel. Merely by way of example, the power module (560) can include a temperature sensor (not shown) for measuring the temperature at or near the back of the panel. See the description about the power module below. The pigtail (580) can be an AC cable with 2, 3, 4, 5 or more conductors and can be terminated by the mating connector (585). The connector (572) and the mating connector (585) can provide the electrical connection of the panel to, such as, for example, other panels. The pigtail (580) can be connected to the power module (560) through a strain relief mechanism (575) which can also provide sealing such as those marketed by Hawke International (www.ehawke.com).

An individual energy conversion cell can be electrically connected to dedicated electronics. As used herein, dedicated electronics refers to the electronics which can sample and/or modify the power input from an individual energy conversion cell and/or a group of cells. The dedicated electronics can be located within the hermetically sealed space of a photovoltaic solar panel. At least a portion of the dedicated electronics can be located out of the hermetically sealed space of a panel. The dedicated electronics can comprise at least one component selected from a bypass diode, a DC-DC converter, a maximum Power Point Tracking (MPPT) circuitry, or the like, or a combination thereof. Merely by way of example, the dedicated electronics can include a low profile bypass diode. A bypass diode can fulfill the requirements of IEC 61730-2 Solar Safety Standards. The bypass diode can comprise at least one selected from a Schottky diode, a PN diode, and a Super Barrier Rectifier (SBR), such as, for example part number SBR10U45SP5 by Diodes Incorporated. Low profile diodes such as Schottky diodes by Microsemi Corporation (part number SFDS1045L and SFDS1045LH) can be used. Description regarding a SBR can be found in, for example, Rodov V. et al. (IEEE Transactions on Industry Applications, vol 44, no. 1, pp 234-237, January/February 2008) and Molding I (Power Systems Design, pp 51-52, December 2008), each of which is incorporated herein by reference. The term “bypass diode” is used in a generic form and it can refer to any device or combination of devices that can have rectifying effects which can pass current in one direction but not the other direction. A DC-DC converter can increase and/or regulate the output voltage of the generated DC of an individual energy conversion cell or a group of cells. An individual energy conversion cell with or without dedicated electronics can be electrically connected, in series, or in parallel, or in a combination thereof, to other individual energy conversion cells, at least partially through the access matrix and/or other groups of cells to form a photovoltaic solar panel. An MPPT circuitry or algorithm can find and track the maximum power point from each energy conversion cell or a group of cells for the prevailing load conditions as well as illumination conditions from the sun, which in turn can determine the optical operating voltage and current for each cell or a group of cells. U.S. Pat. Nos. 6,046,919; 7,394,237; and 7,479,774 describe various methods available for MPPT algorithms, each of which is incorporated herein by reference. Briefly, the DC power from the solar panel can be calculated using the signals from the DC voltage sensor and/or current sensor within a time interval. This power can be compared to power within the same time interval but from an earlier time point. Concurrently the DC voltage can be compared to the voltage of an earlier point. If there is a change in the DC power and/or DC voltage, the voltage can be changed by an incremental amount according to the rate at which the power changes with voltage. The calculating and/or comparing of the power and voltage can be repeated at different times. The time interval can be pre-determined. The time interval can be fixed. Merely by way of example, the time interval can be from about 1 millisecond to about 60 seconds, or from about 10 milliseconds to about 30 seconds, from about 50 milliseconds to about 10 seconds. The time interval can be varied. Merely by way of example, the time interval can change with the magnitude of the change in power and/or voltage of the previous cycle of calculating and/or comparing. Such algorithms can be embedded in the microcontroller within the power module.

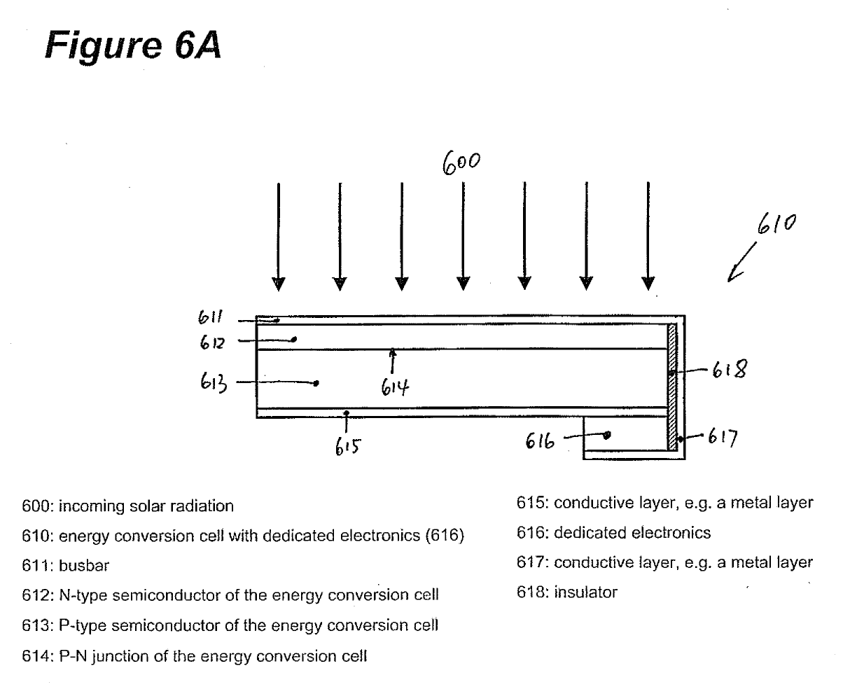

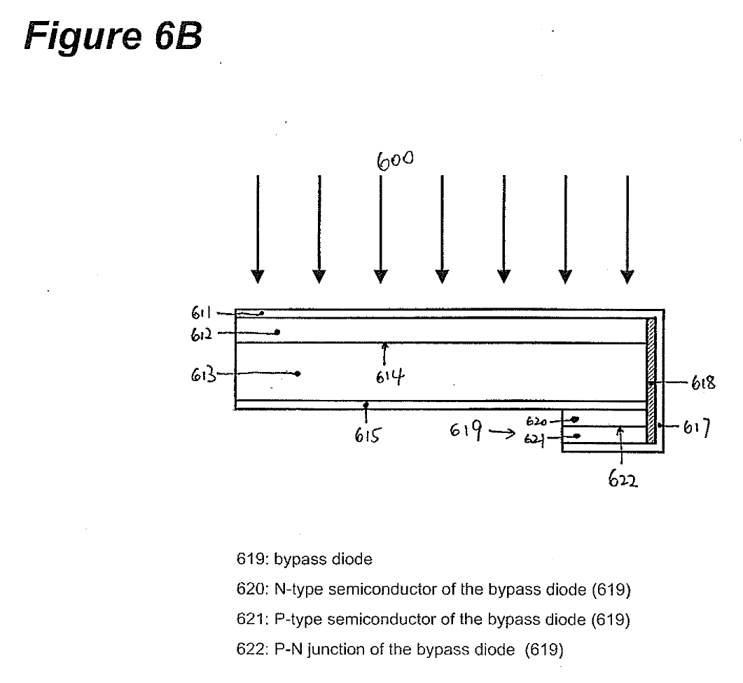

FIG. 6A illustrates a schematic representation of an exemplary implementation of an energy conversion cell with dedicated electronics. The energy conversion cell can be a photovoltaic cell. In FIG. 6A, 600 illustrates incoming solar radiation; 610 illustrates an energy conversion cell; 611 illustrates the busbar on the top side where the incoming solar radiation (600) strikes, which can be electrically connected to the N-type semiconductor (612) of the energy conversion cell (610) and can collect the charge carriers, e.g., electrons, reaching the top side of the energy conversion cell (610); 612 illustrates N-type semiconductor; 613 illustrates P-type semiconductor; 614 illustrates the P-N junction; 615 illustrates a conductive layer, e.g. a metal layer, which can be electrically connected to the P-type semiconductor (613) of the energy conversion cell (610), and/or the dedicated electronics (616); 616 illustrates the dedicated electronics electrically connected to the energy conversion cell (610), wherein the dedicated electronics can comprise a bypass diode, a DC-DC converter, a MPPT circuitry, or an integrated circuit chip with embedded algorithms that performs specific tasks, or the like, or a combination thereof; 617 illustrates a electrically conductive layer, e.g. a metal layer, which can be electrically connected to the N-type semiconductor (612) of the energy conversion cell (610), and/or the busbar (611), and/or the dedicated electronics (616); and 618 illustrates an insulator which can insulate the N-type semiconductor (612) and the P-type semiconductor (613) from the busbar (611) and the conductive layer (617).

FIG. 6B illustrates an exemplary energy conversion cell with a dedicated electronics including a bypass diode (619). The same numbers in FIG. 6B illustrate the same parts as in FIG. 6A. 619 illustrates the bypass diode (619); 620 illustrates the N-type semiconductor of the bypass diode (619), and 621 illustrates the P-type semiconductor of the bypass diode (619); and 622 illustrates the P-N junction of the bypass diode (619).

It is understood that FIG. 6A and FIG. 6B are for illustration purposes only and are not intended to limit the scope of the application. An energy conversion cell with a P-type semiconductor closer to the top side of the cell and a N-type semiconductor closer to the bottom side of the cell can be used in an arrangement similar to that is described in FIG. 6A and FIG. 6B.

The top side of the energy conversion cell can include an anti-reflection (AR) coating (not shown in FIG. 6A or FIG. 6B). An anti-reflection coating can comprise, such as, for example, silicon nitride which can be at least partially metalized by, for example, screen printing. The top side of the energy conversion cell where the solar radiation strikes can comprise an electrically conductive material which can have a diverse geometry. See, for example, Green M. A. (“Solar Cells”, University of New South Wales, December of 1998, pp 153-161), which is incorporated herein by reference. The electrically conductive material can collect the charge carriers, e.g., electrons, reaching the top side. The electrically conductive material can comprise a wide track, which can be referred to as the “busbar” (611). An energy conversion cell can have one or more bus bars. The busbars can be electrically connected to the electrodes. The busbar (611) can be located on the top side of an energy conversion cell, in order to electrically connect several energy conversion cells, for example, in series, or in parallel, or in a combination thereof. The busbar (611) can transfer charge carriers out of the energy conversion cells. A discussion regarding a busbar (611) can be found in U.S. Pat. No. 4,542,258 which is incorporated herein by reference. The bottom side of an energy conversion cell can be covered with a material which can be reflective and/or conductive. The material can be, such as, for example, a metal. The metal can comprise, such as, for example, aluminum. There can be conductive lines such as, for example, silver in electrical contact with the material on the bottom side of the cell. The conductive lines can be similar to busbar (611) on the top side of the cell. The conductive lines can collect and/or transfer charge carriers reaching the bottom side of the energy conversion cell out of the cell.

The dedicated electronics as exemplified as 616 in FIG. 6A or the bypass diode as exemplified as 619 in FIG. 6B can occupy a volume from about 0.1 mm³ to about 100 mm³, or from about 1 mm³ to about 80 mm³, or from about 5 mm³ to about 50 mm³, or from about 10 mm³ to about 40 mm³, or from about 20 mm³ to about 30 mm³, or about 25 mm³. The volume can comprise a cross-sectional shape selected from rectangular, square, round, ellipse, rhomboid, trapezoidal, or the like, or a combination thereof, in the direction parallel to the top side and/or the bottom side of the energy conversion cell. At least two sides of this volume can be metalized to serve as polarities of the bypass diode to electrically connect the bypass diode to the energy conversion cell, without limitation, by means of thermo-compression bonding or conductive adhesive. An insulator (618) can be provided as exemplified in FIG. 6A and FIG. 6B to avoid an electrical short circuit among, such as, for example, the N-type semiconductor (612), the P-type semiconductor (613), and the dedicated electronics (616), e.g., the bypass diode (619). The insulator (618) can comprise vacuum, air or a suitable dielectric material. A suitable dielectric material can comprise at least one selected from ethylene vinyl acetate (EVA) and polyvinyl fluoride (PVF). It is understood that the parts in FIG. 6A and FIG. 6B are referred to for illustration purposes only, and are not limiting as to the scope of the instant application. It is within the scope of this instant application that the bypass diode is unpackaged and in the form of a fully processed wafer, in which case the problem of attaching the bypass diode to the solar cell becomes wafer to wafer bonding which can be achieved by thermo-compression techniques using soft metals such as indium for example.

A bypass diode can comprise any device with rectifying capability The following references are generally directed to a bypass diode: U.S. Pat. Nos. 4,542,258; 4,577,051; 4,759,803; 5,616,185; 6,262,358; 6,313,395; 6,326,540-B1; 6,690,041-B1; 6,799,742; 6,979,771; 7,449,630-B2, each of which is incorporated herein by reference.

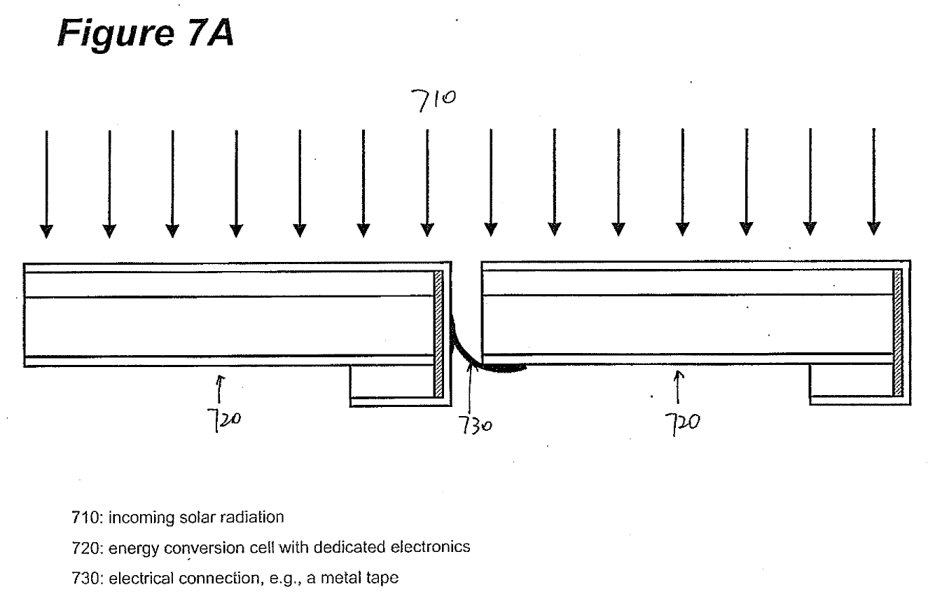

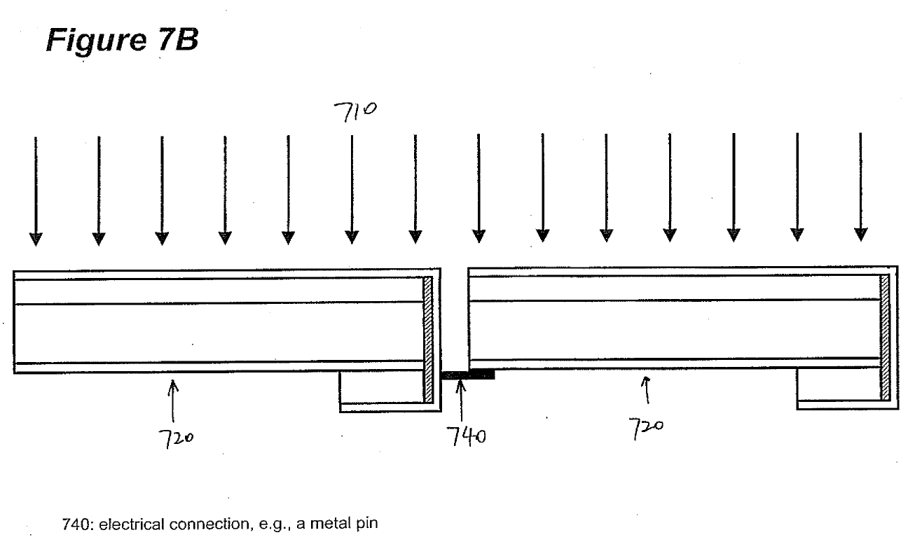

Energy conversion cells with dedicated electronics as exemplified in FIG. 6A and FIG. 6B can be electrically connected by, such as, for example, a metal tape, a metal pin, or the like, or a combination thereof. Merely by way of example, FIG. 7A shows that two such energy conversion cells (720) can be serially connected using metal tapes (730) to form a string; and FIG. 7B shows that two such energy conversion cells (720) can be serially connected using metal pins (740) to form a string. A metal tape (730) (FIG. 7A) or a metal pin (740) (FIG. 7B) can electrically connect the positive polarity of an energy conversion cell to the negative polarity of the next energy conversion cell to form a serial connection. A metal tape or a metal pin can electrically connect the positive polarity of an energy conversion cell to the positive polarity of the next energy conversion cell, and connect the negative polarity of the energy conversion cell to the negative polarity of the next energy conversion cell to form a parallel connection.

Energy conversion cells with dedicated electronics as exemplified in FIG. 6A and FIG. 6B can be electrically connected together as exemplified in FIG. 7A and FIG. 7B to form a string and then be packaged into a photovoltaic solar panel. As used herein, a string refers to energy conversion cells or photovoltaic solar panel which are electrically connected in series. Merely by way of example, a string can refer to a group of energy conversion cells in serial connection within a panel; a string can refer to groups of energy conversion cells in serial connection within a panel; and a string can refer to several panels in serial connection.

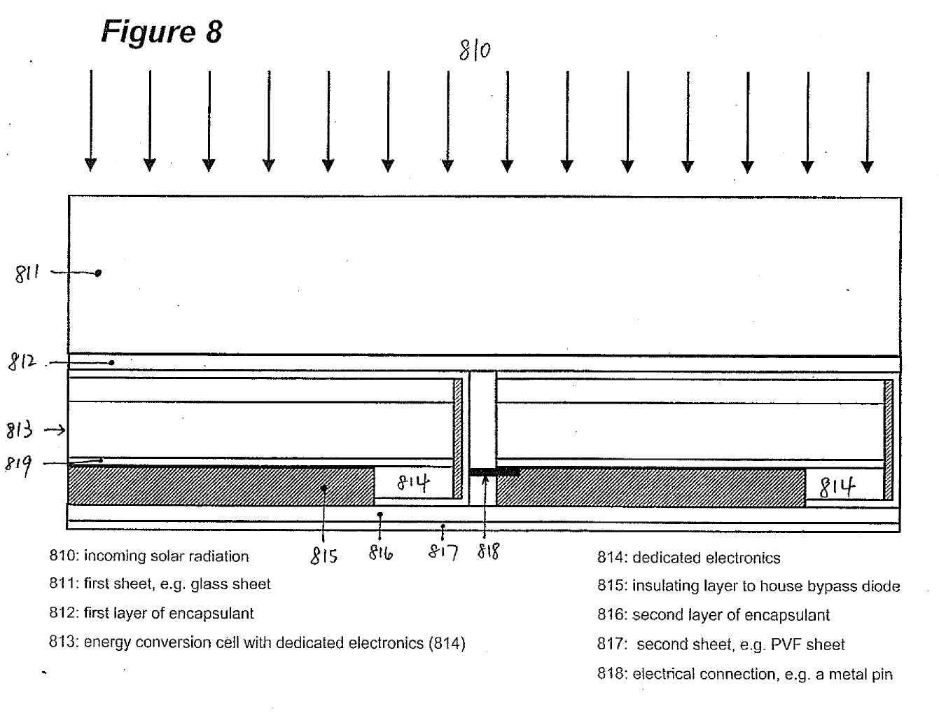

FIG. 8 shows an exemplary packaging of such energy conversion cells with dedicated electronics into a photovoltaic solar panel. 810 illustrates incoming solar radiation. 811 illustrates a first sheet, e.g. a sheet of glass, or more preferably low-iron tempered glass. The first sheet (811) can comprise an anti-reflection (AR) coating. 812 illustrates a first layer of encapsulant. 813 illustrates the energy conversion cells with a conductive layer (819) and dedicated electronics (814) on the bottom side. The dedicated electronics (814) can include a bypass diode, a DC-DC converter, a MPPT circuitry, or the like, or a combination thereof. The energy conversion cells can be connected in series through an electrical connection (818), such as, for example, a metal tape, a metal pin, or the like, or a combination thereof. 815 illustrates an insulating layer. 816 illustrates a second layer of encapsulant. 817 illustrates a second sheet. The second sheet (817) can comprise polyvinyl fluoride (PVF) film. The first layer of encapsulant (812) and/or the second layer of encapsulant (816) can comprise ethylene vinyl acetate (EVA). The insulating layer (815) can be provided in order to house the dedicated electronics (814), thereby providing two parallel surfaces for the energy conversion cells in conjunction with the second sheet (817). This structure can then be encapsulated by means of two layers of encapsulant (812 and 816) using for example thermo-compression lamination. 812, 813, 814, 815 and 816 can be sealed between the first sheet (811) and the second sheet (817) to generate the hermetically sealed space. The exemplary arrangement of the energy conversion cells with dedicated electronics can facilitate manufacturing the panel due to, such as, for example, the energy conversion cells (813) distributed across a substantially two-dimensional plane, and/or the dedicated electronics (814) housed in an insulating layer (815) with at least two parallel surfaces (e.g., one parallel surface in contact with the conductive layer (819) on the bottom side of the cell, and the other parallel surface in contact with the second layer of encapsulant (816)). This can facilitate the lamination and packaging of the energy conversion cells (813) with or without dedicated electronics (814) into the panel with at least two parallel surfaces (e.g., 817 and 812) and the generating of the hermetically sealed space. Solar radiation can strike on the first sheet (811) and reach the energy conversion cells (813) for photovoltaic generation.

A group of cells can be electrically connected to dedicated electronics. The dedicated electronics can comprise at least one component selected from a bypass diode, a DC-DC converter, an MPPT circuitry, or an integrated circuit chip with embedded algorithms that performs specific tasks, such as for example MPPT algorithm, or the like, or a combination thereof. The dedicated electronics electrically connected to a group of cells can be similar to what is described above for dedicated electronics electrically connected to an individual energy conversion cell. A group of cells with or without dedicated electronics can be electrically connected, in series, or in parallel, or in a combination thereof, to individual energy conversion cells and/or other groups of cells and be sealed within a hermetically sealed space in a photovoltaic solar panel, as described above.

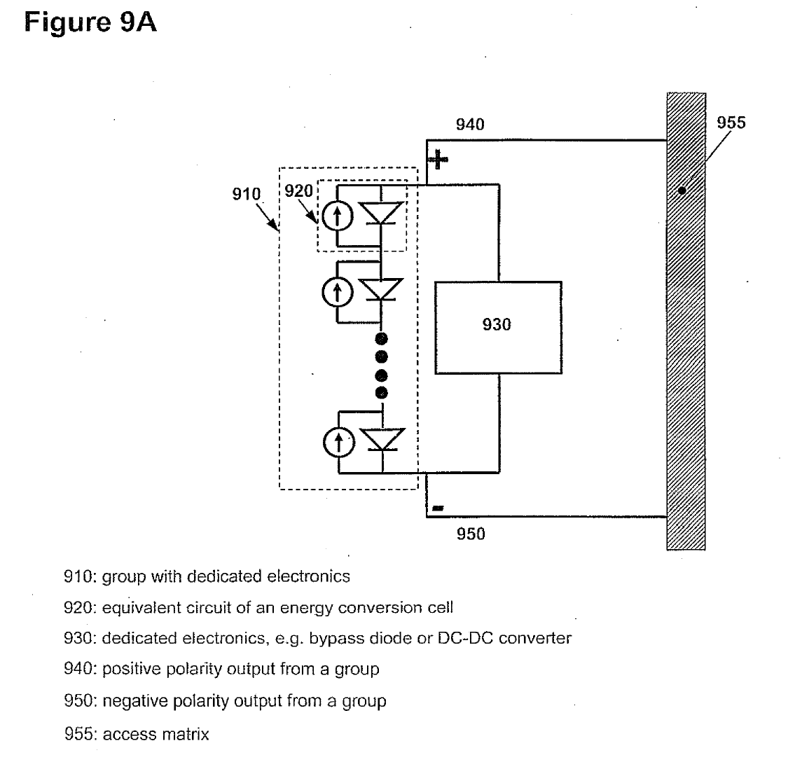

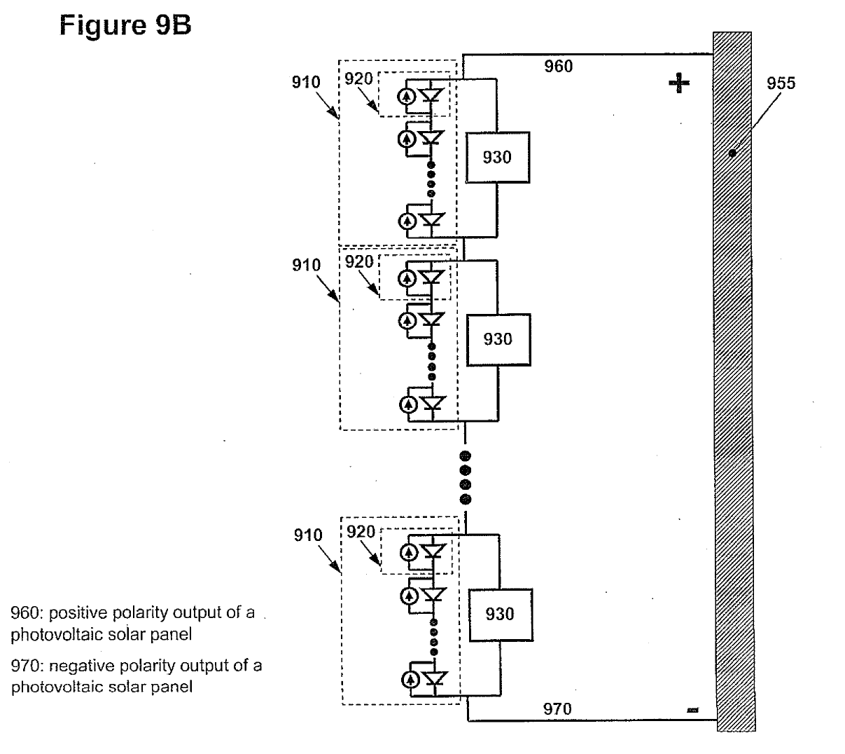

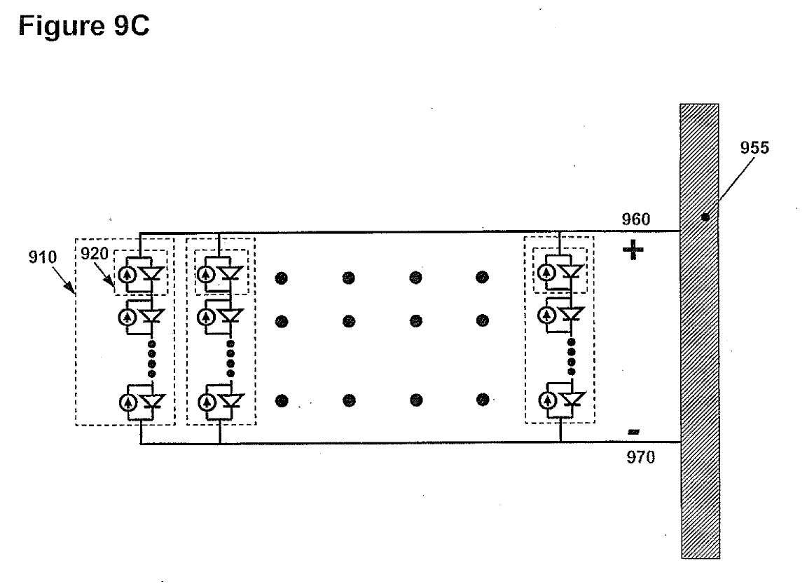

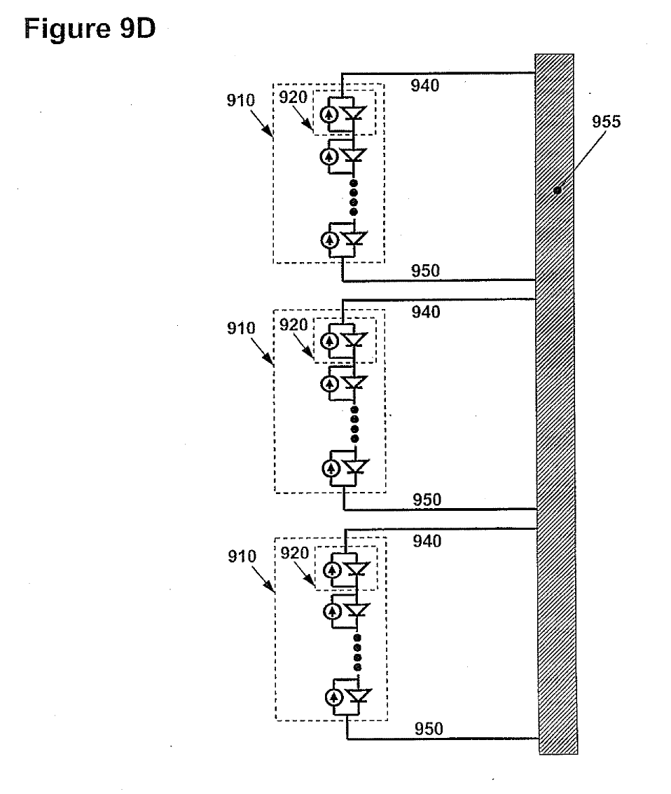

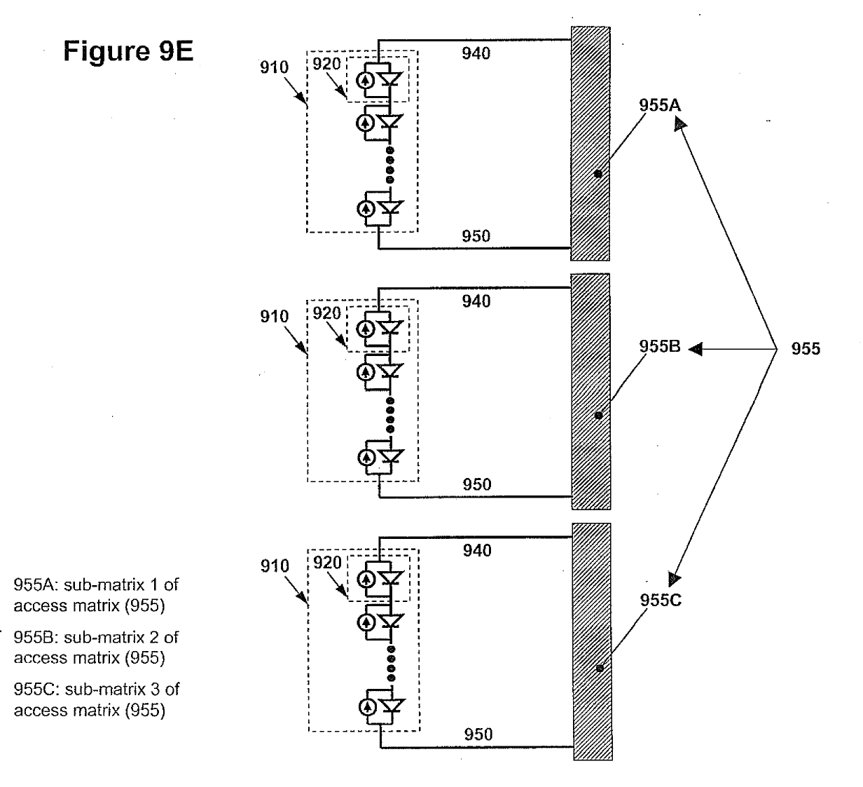

FIG. 9A illustrates a schematic representation of an exemplary group (910) with dedicated electronics (930). The group (910) can comprise one energy conversion cell (920). As known to those skilled in the art each energy conversion cell (920) can be represented by a current source in parallel with a diode. The group can comprise multiple energy conversion cells (920). The energy conversion cells (920) within a group (910) can be electrically connected in series. The group (910) can be electrically connected to dedicated electronics (930). The dedicated electronics (930) can comprise at feast one component selected from a bypass diode, a DC-DC converter, a MPPT circuitry, or an integrated circuit chip with embedded algorithms that performs specific tasks, or the like, or a combination thereof. The group (910) with its dedicated electronics (930) can comprise a positive polarity output (940) and a negative polarity output (950). The group (910) can be electrically connected to an access matrix (955). The access matrix (955) can comprise at least one electrical connection (not shown) to location outside of the group (910). The electrical connection of the group (910) to its dedicated electronics (930) can be through the access matrix (955).

FIG. 9B illustrates a schematic representation of an exemplary photovoltaic solar panel. The panel can include multiple groups (910). Each group (910) can comprise at least one energy conversion cell (920). The at least one energy conversion cell (920) in each group (910) can be electrically connected in series. Each group (910) can comprise dedicated electronics (930). The dedicated electronics (930) can comprise at least one component selected from a bypass diode, a DC-DC converter, a MPPT circuitry, or an integrated circuit chip with embedded algorithms that performs specific tasks, or the like, or a combination thereof. The multiple groups (910) can be electrically connected in series. The groups (910) in serial connection can be electrically connected to the access matrix (955) through the positive polarity output (960) and the negative polarity output (970). All or partial connection of the cells within groups (910) and/or connection of the dedicated electronics (930) can take place through the access matrix (955). The power generated by the panel can be delivered out of the panel to, such as, for example, other electrical devices for further processing, and/or appliances, and/or power grids, via the access matrix (955).

FIG. 9C illustrates a schematic representation of an exemplary photovoltaic solar panel. The panel can include multiple groups (910). Each group (910) can comprise at least one energy conversion cell (920). The at least one energy conversion cell (920) in each group (910) can be electrically connected in series. The multiple groups (910) can be electrically connected in parallel. Individual energy conversion cells (920) and/or groups of cells (910) can include dedicated electronics. At least one branch of the parallel connection can include multiple groups of cells (910) in serial connection, in parallel connection (as exemplified in FIG. 4B), or in a combination thereof, wherein each group can comprise a dedicated electronics (930). The groups (910) in serial connection can be electrically connected to the access matrix (955) through the positive polarity output (960) and the negative polarity output (970). The parallel connection of the groups (910) can also be established by the access matrix as was shown in FIG. 4B. The power generated by the panel can be delivered out of the panel to, such as, for example, other electrical devices for further processing, and/or appliances, and/or power grids.

FIG. 9D illustrates a schematic representation of an exemplary photovoltaic solar panel. The panel can include multiple groups (910). Each group (910) can comprise one or more energy conversion cells (920). The one or more energy conversion cells (920) in each group (910) can be electrically connected in series. Individual energy conversion cells (920) and/or groups of cells (910) can include dedicated electronics. Each of the multiple groups (910) can be electrically connected to the access matrix (955) through the positive polarity output (940) and the negative polarity output (950). The groups (910) can be in electrical connection with each other in series, or in parallel, or in a combination thereof, via the access matrix (955). The power generated by the panel can be delivered out of the panel to, such as, for example, other electrical devices for further processing, and/or appliances, and/or power grids, via the access matrix (955). The groups (910) can deliver power out of the panel via the access matrix (955) independently from each other.

FIG. 9E illustrates a schematic representation of an exemplary photovoltaic solar panel. The panel can include multiple groups (910). Each group (910) can comprise at least one energy conversion cell (920). The at least one energy conversion cell (920) in each group (910) can be electrically connected in series. Individual energy conversion cells (920) and/or groups of cells (910) can include dedicated electronics. Each of the groups (910) can be electrically connected to a sub-matrix (955A, or 955B, or 955C) of the access matrix (955) through the positive polarity output (940) and the negative polarity output (950). The sub-matrices (955A, or 955B, or 955C) of the access matrix (955) can be isolated from each other physically and/or electrically, as shown in the figure. The power generated by the panel can be delivered out of the panel to, such as, for example, other electrical devices for further processing, and/or appliances, and/or power grids, via the access matrix (955). The groups (910) can deliver power out of the panel via the sub-matrices (955A, or 955B, or 955C) of the access matrix (955) independently from each other.

A photovoltaic solar panel can be electrically connected to a power module located outside the panel. The power module can be potted in a suitable epoxy which can be bonded to an external surface of the panel; or it can be placed in a suitable box which can be attached to an external surface of the panel. As used herein, an external surface of the panel refers to a surface facing outward to the surroundings, not facing the inside of the panel. Merely by way of example, the power module can be attached to an external surface of the second sheet of the panel. The power module can be hermetically sealed in a space, e.g. a box. Merely by way of example, the hermetically sealed space housing the power module can be formed by filling the entire physical space of the power module with a suitable epoxy such as those offered by Dow Chemical. The power module can comprise at least one component selected from a bypass diode, a super barrier rectifier, a maximum peak power tracking (MPPT) circuit, a transformer, a DC-to-DC converter, a DC-to-AC inverter, a micro-controller, a microprocessor, an analog-to-digital converter, a digital-to-analogue converter, a temperature sensor, a humidity sensor, a frequency measurement device, a memory device with embedded algorithms such as for example MPPT algorithms, or the like, or a combination thereof, or an integrated circuit with embedded algorithms, or an ASIC (application specific integrated circuit). The DC-to-AC inverter can comprise anti-islanding, over current, undercurrent, over voltage, under voltage provisions, or the like, or a combination thereof. The power module can comprise a circuitry. The circuitry can be assembled on a printed circuit board or a chip. The power module can comprise at least one power line communication (PLC) chipset. The operation of the power module can be monitored or the power module can respond to the feedback or control from locations outside the power module, or outside the hermetically sealed space housing the power module. The power module can comprise at least one WiFi or cell based chipset, such as those used in cellular communication of cell phones. Merely by way of example, the power module can receive instructions from a remote control center of a power grid comprising multiple panels through WiFi, cellular network, or PLC and can automatically adjust the operation parameters of the panel and the power module accordingly. The power module can send the operation parameters back to the remote control center for monitoring purposes so that the remote control center can adjust the operation of the other panels within the same power grid. The operation parameters of a panel can comprise, such as, for example, solar energy available, temperature, voltage, current, energy conversion efficiency (e.g. the ratio of solar energy incident on the panel to power generated by the panel), or the like, or a combination thereof. The operation parameters of a power module can comprise, such as, for example, voltage and/or current of the power input from the panel, voltage and/or current of the power output to power grid or appliance, energy conversion efficiency (e.g. the ratio of the power input to output), or the like, or a combination thereof.

Examples of useful components which can be incorporated in the dedicated electronics and/or the power module can be found in Mohen N, et al. (“Power Electronics, Converters, Applications, and Design,” John Wiley & Sons, Inc. pp 161-297, USA ISBN 978-0-471-22693-2); Telecom, Datacom and Industrial Power Products (32 pages), Vol 3, by Linear Technology; Micrel switch-mode selection guide by Micrel Incorporated, February 2008 (pages 11, 15); John Shanon, Design Note 1012, entitled “Shrink Solar Panel Size by Increasing Performance” available on Linear Technology website; U.S. Patent Application Publication No. 2009/0020151, entitled “Method and Apparatus for Converting a Direct Current to Alternating Current Utilizing a Plurality of Inverters”, filed Jul. 16, 2007, and U.S. Patent Application Publication No. 2009/0160259, entitled “Distributed Energy Conversion Systems”, filed Dec. 20, 2008, each of which is incorporated herein by reference.

The access matrix can comprise a hierarchy of electrical connection to individual energy conversion cells and/or different groups of cells within a photovoltaic solar panel. Merely by way of example, a photovoltaic solar panel can comprise sixty energy conversion cells. The energy conversion cells can be grouped such that each group can comprise six electrically connected energy conversion cells. The panel can comprise ten groups of energy conversion cells. Every two groups can form a cluster. The panel can comprise five clusters. The term cluster is used herein merely for the purpose of illustration, and is not intended to indicate any change in the physical distribution of the energy conversion cells within the panel. The access matrix can comprise three levels of conductors. The first level can electrically connect each group to a bypass diode and a DC-DC converter and MPPT circuitry with embedded algorithm to optimize the power output of the group; the second level can electrically connect each cluster to an inverter to invert the direct current (DC) to the alternating current (AC); and a third level can electrically connect the five clusters to deliver the generated power to an AC output. In this way, a weak energy conversion cell can only affect the power output of the group which it belongs to, and does not affect the power output of the groups within the same cluster, or the power output of the other clusters within the same panel. It is understood that the example is described for illustration purposes only, and is not intended to limit the scope of the application. The access matrix can provide electrical access to individual energy conversion cells and/or groups of cells within the hermetically sealed space within the panel for electrical devices located within and/or outside of the panel.

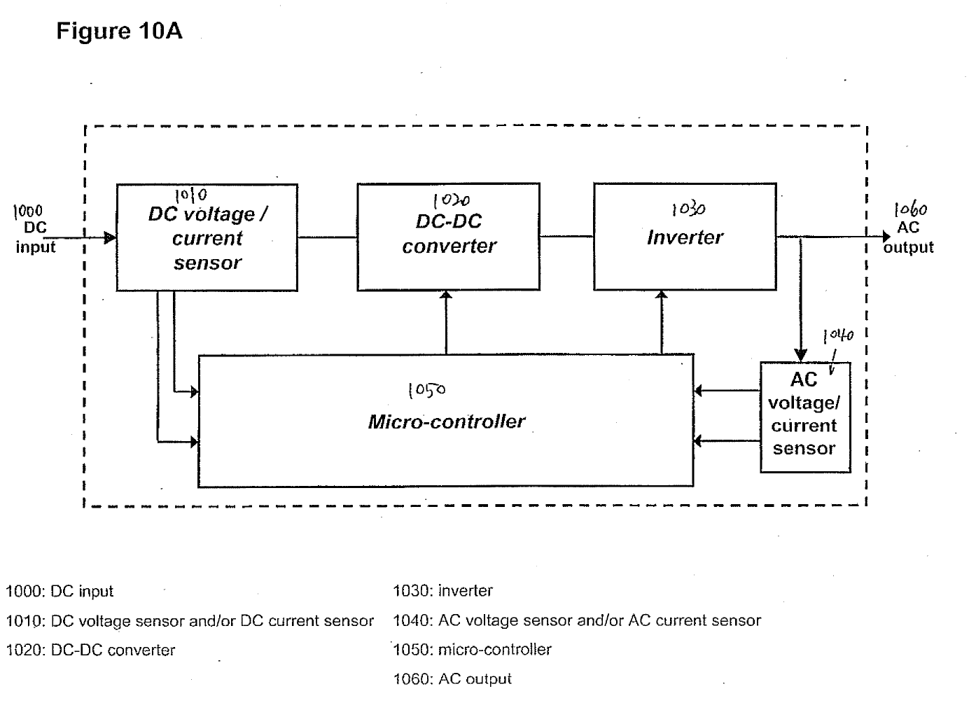

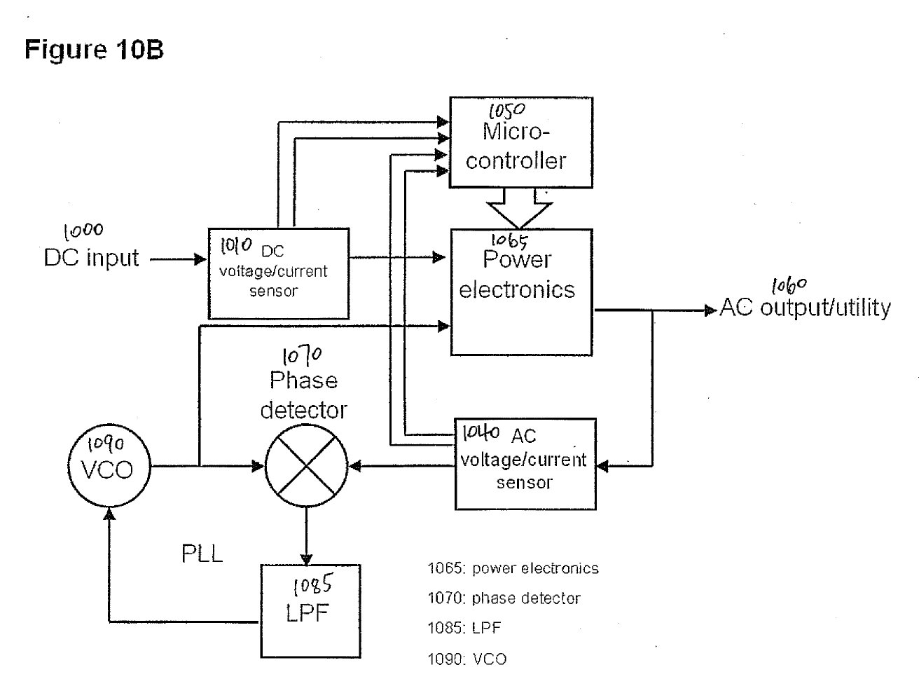

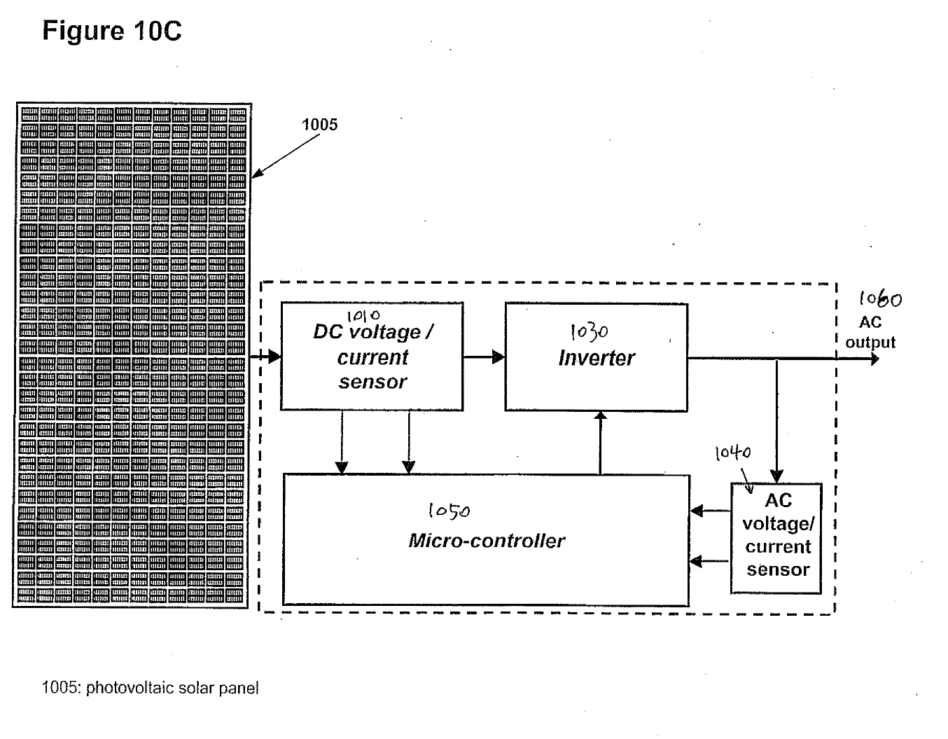

FIG. 10A shows a block diagram of an exemplary power module for its corresponding photovoltaic solar panel according to one aspect of the current application. The combination of the photovoltaic solar panel and the power module can be referred to as an AC panel when the output of the panel modified by the power module is AC power. The panel can comprise multiple energy conversion cells (not shown). The energy conversion cells can be divided into groups. Each group can comprise at least one energy conversion cell. Merely by way of example, the panel can comprise any one of the embodiments exemplified in FIG. 9A to FIG. 9E. 1000 illustrates the DC input generated by individual energy conversion cells and/or groups of cell exemplified in FIG. 9A to 9E; 1010 illustrates the DC voltage sensor and/or current sensor; 1020 illustrates the DC-DC converter; 1030 illustrates the DC-AC inverter; 1040 illustrates the AC voltage sensor and/or current sensor; 1050 illustrates the micro-controller; and 1060 illustrates the AC output. The DC voltage sensor and/or current sensor (1010) can measure the voltage and/or current from the solar panel (not shown) at input (1000) to examine whether the DC input (1000) has sufficient voltage and/or current as suitable input for the following electrical devices in which the DC input can be sampled and/or modified to generate the AC output (1060). Another reason for measuring the input voltage and current can be to ensure that the panel is operating at maximum peak power point. The current sensor can be a high impedance amplifier measuring the voltage across a sense-resistor or be based on hall effect sensor technology such as ACS714 by Allegro Microsystems Inc. The voltage sensor can be a suitable resistive voltage divider. The DC-DC converter (1020) can boost the voltage the DC voltage and/or provide isolation if necessary. The DC-DC converter can be, without any limitation, boost, buck-boost, flyback, push-pull, half bridge, or full bridge. The inverter (1030) can invert the DC output of the DC-DC converter to AC. This AC can be used as AC output (1060) to power appliances; or it can be fed to power grid (also referred to utility grid). Furthermore the AC power can be single-phase or three-phase. Examples of useful components which can be incorporated in the dedicated electronics and/or the power module can be found in Mohen N, et al. (“Power Electronics, Converters, Applications, and Design,” John Wiley & Sons, Inc. pp 161-297, USA ISBN 978-0-471-22693-2); datasheet of part number PS21963-4, PS21963-4A, and PS21963-4C and the Application Note DK-PS21962, DK-PS21963, DK-PS21964, DK-PS21965 Version 4 Super Mini DIP-IPM Basic Development Board by Powerex, Inc, 173 Pavilion Lane, Youngwood, Pa. 15697-1800; Wibawa T. Chou, “Build an Efficient 500W Solar-Power Inverter using IGBTs”, Electronic Design (2009), pages 43-46, available at www.electronicdesign.com, each of which is incorporated herein by reference. The AC voltage and/or current signal measured by the AC voltage sensor and/or current sensor (1040) can be fed to the micro-controller (1050). The DC voltage and/or current signal measured by the DC voltage sensor and/or current sensor (1010) can also be fed to the micro-controller (1050). The micro-controller (1050) can adjust the DC-DC converter (1020) and/or the inverter (1030) in real time based on the DC voltage and/or current signal and the AC voltage and/or current signal, such that the AC output can be optimized. In order to convert the DC to AC, the AC voltage sensed can be used as a reference to current which can be delivered out of the panel as output. This way the voltage can remain phase locked to the output current from the inverter. The inverter can comprise 4 or 6 MOSFET (Metal Oxide Semiconductor Field Effect transistor) or IGBTs (Insulated Gate Bipolar Transistor) for single-phase and three-phase, respectively. There are a wide variety of ways of driving the gates of these devices. For example, all the gates can be driven at a high switching frequency; or the gates on the high voltage side can be driven at the high frequency switching frequency, and the gates on the low voltage side can be driven by the line frequency of 40-70 Hz, preferably and nominally 50 or 60 Hz. Furthermore, both the DC-DC converter and the inverter can deploy a pulse width modulation (PWM) scheme in order to regulate their corresponding outputs. There can be several vendors of suitable microcontrollers for this application and they include, without limitation, Microchip, Texas Instruments, and Freescale. The two arrows pointing from 1010 to 1050 indicate that there can be DC voltage signal and current signal from 1010 to 1050; and the two arrows pointing from 1040 to 1050 indicate that there can be AC voltage signal and current signal from 1040 to 1050.

The AC panel can generate AC power and can be connected to utility. The AC panel can provide anti-islanding provisions. Islanding of a grid to which an AC panel or AC panels can be connected can occur when a section of the utility system containing the AC panel or AC panels is disconnected from the main utility, while the AC panel or AC panels continue to energize the utility lines in the isolated section (called an island). Unintended islanding can be of concern as it can pose a hazard to utility, consumer equipment, maintenance personnel and the general public. Anti-islanding algorithms such as those developed at Sandia National Labs (see for example J. Stevens, R. Bonn, J. Ginn, S. Gonzalez, and G. Kern, “Development and testing of an approach to anti-islanding in utility-interconnected photovoltaic systems,” Sandia Report SAND 2000-1939, August, 2000, each of which is incorporated herein by reference) can be incorporated in the power module to turn off the power module in case there are certain irregularities in the utility power. The embedded algorithms in the power module can comprise anti-islanding algorithms. These algorithms can check for the condition of the utility, if there is a change in the voltage level and/or line frequency, the anti-islanding algorithms can force the power module to shut down and not to feed the grid with power. More details of such algorithms can be found, for example, at http://www.electricdistribution.ctc.com/pdfs/Ye_PES03-179.pdf, which is incorporated herein by reference.

FIG. 10B shows a block diagram of an exemplary power module for its corresponding photovoltaic solar panel. The combination of the photovoltaic solar panel and the power module can be referred to as an AC panel when the output of the panel modified by the power module is AC power. The same numbers in FIG. 10B illustrate the same parts as in FIG. 10A. 1000 illustrates the DC input generated by individual energy conversion cells and/or groups of cell; 1010 illustrates the DC voltage sensor and/or current sensor; 1040 illustrates the AC voltage sensor and/or current sensor; 1050 illustrates the micro-controller; 1060 illustrates the AC output; 1065 illustrates the power electronics which can include DC-DC converters and an inverter; 1070 illustrates a phase detector; 1085 illustrates a low pass filter (LPF); and 1090 illustrates a voltage controlled oscillator (VCO). As used herein, power electronics can refer to one or more electrical devices or components of the power module. As used herein, an inverter can refer to a DC-AC inverter. A phase-locked-loop (PLL, not shown in the figure) can comprise a phase detector (1070), a low pass filter (LPF, 1085) and a voltage controlled oscillator (VCO, 1090). A PLL can provide a phase-locked sample of AC from AC voltage sensor and/or current sensor (1040) to the power electronics (1065) of the panel. A voltage controlled oscillator (VCO, 1090) can be set to oscillate at a frequency of about 50 to about 60 Hz nominally. The AC output (1060) can be sampled in the AC voltage sensor and/or current sensor (1040), wherein the generated AC voltage and/or current signal can be fed to the phase detector (1070). The output of the phase detector (1070) can be fed back to the VCO (1090) through a low pass filter (LPF, 1085). This way the output of the VCO (1090) can remain phase locked to, such as, for example, the utility electricity in a power grid. It is clear to those skilled in the art that the PLL can be implemented in analog or digital electronics. The DC input (1000) can be fed to the DC voltage sensor and/or current sensor (1010) to examine whether it is suitable input for the following electrical devices in which the DC input can be sampled and modified to generate the AC output (1060). Furthermore the sample of the DC input voltage and current can predict the optimum operating point for the panel through a maximum peak power tracking algorithm. If the DC input is suitable, the DC voltage and/or current signal can be fed to the micro-controller (1050); and the DC input (1000) can be delivered to the power electronics (1065) in which it can be modified to the AC output (1060). The AC output (1060) can be suitable for utility. The signal from the PLL can be fed to the micro-controller (1050). The micro-controller (1050) can adjust in real time based on the signal such that the power electronics (1065), e.g., the DC-DC converter and/or DC-AC inverter, can perform to optimize the AC output (1060).

FIG. 10C shows a block diagram of an exemplary photovoltaic solar panel and the power module. The combination of the photovoltaic solar panel and the power module can be referred to as an AC panel when the output of the panel modified by the power module is AC power. The panel can comprise multiple energy conversion cells. The same numbers in FIG. 10C illustrate the same parts as in FIG. 10A and/or FIG. 10B. 1005 illustrates a photovoltaic solar panel which can generate a high DC voltage thereby eliminating the need for a DC-DC converter. From a given surface area of the panel a higher DC voltage can be attained by increasing the number of cells and using smaller cells. Depending on the power level and design, a DC-DC converter can have an efficiency of about 90-95%; given a higher starting DC voltage and by eliminating the DC-DC converters a higher overall efficiency can be achieved. 1010 illustrates the DC voltage sensor and/or current sensor; 1030 illustrates the DC-AC inverter; 1040 illustrates the AC voltage sensor and/or current sensor; 1050 illustrates the micro-controller; and 1060 illustrates the AC output. Merely by way of example, if the root mean square (RMS) of the utility voltage is 120V, the peak voltage is approximately 170V. For an efficient AC panel and so that AC current can be pushed onto utility effectively, the panel can have an output of a voltage higher than 170V to allow for potential drops in the inverter or any other power electronics. In view of this the panel can generate DC voltage of at least about 80%, or at least about 100%, or at least about 120%, or at least about 140%, or at least about 160%, or at least about 180%, or at least about 200% of the AC output voltage. As such, in view of the fact that each cell can generate approximately 0.6V, a panel with 360 cells generates approximately 216V which can be adequate to directly be fed into the inverter without the use of DC-DC converter to increase the voltage. A panel that can accommodate 360 smaller cells can have approximately the same dimensions as a panel of a 10×6 matrix with each cell being 156 mm×156 mm (for example JAP6 series marketed by JA Solar www.jasolar.com) and the power output can be essentially the same. As used herein, a 10×6 matrix means that the matrix comprises 60 energy conversion cells which are arranged in 10 groups, each group comprising 6 energy conversion cells. Such dimensions are about 992 mm×1650 mm or smaller. For a given output power from the panel, the smaller the panel is, the more efficient the panel is in terms of power per unit area that it can generate. For a panel with larger energy conversion cells, it can generate power of lower voltage and higher current; and for a panel with smaller energy conversion cells, it can generate power of higher voltage and lower current. The energy conversion cells can be used in a 6×60 matrix with each cell being 156 mm×26 mm. Alternatively, the cells can be in a 12×30 matrix with each cell being 78 mm×52 mm. The cells can be connected in series through the access matrix. It can be advantageous to have an energy conversion cell which can generate a higher voltage than 0.6V. According to another aspect of the current application, such a high voltage cell is described below. It is also within the scope of this application to have such a high voltage panel by using thin film deposition technologies in conjunction with laser scribing to define, for example, 360 cells or even more cells within a given surface area. For example, a MPE-380-AL-01 panel manufactured by Schuco (www.schuco-isa.com) uses 2592 cells in a 12×216 matrix leading to a 201V DC voltage. Another example is provided by using organic photovoltaic (OPV) cells such as Power Plastic® materials produced Konarka Technologies, Inc (www.konarka.com). Such materials can, for example, cover the facade of a building and be connected to a power module described herein in order to generate AC power compatible with utility electricity. The DC voltage sensor and/or current sensor (1010) can measure the voltage and/or current of the DC input from the panel (1005) to examine whether the DC input has sufficient voltage and/or current as suitable input for the following electrical devices in which the DC input can be sampled and modified to generate the AC output (1060) and deliver maximum peak power. U.S. Pat. Nos. 6,046,919; 7,394,237; and 7,479,774 each incorporated herein by reference each describe various methods available for MPPT algorithms. The operation mechanism can be similar to what has been described above.

Merely by way of example, the power module can comprise a DC-to-DC converter, an inverter, a power amplifier (e.g. a voltage amplifier or a current amplifier), reactive circuit components such as transformers, inductors, and capacitors, which can be used to boost the voltage or current of the power output, or the like, or a combination thereof. The power electronics (1065) can comprise other equivalent circuitry, digital or analog, for converting DC to AC. For example, concepts used in switching power supplies as applied to this application can be within the scope of this application; and concepts used for kW level inverters when they are used for a few watts from each panel can be within the scope of this application. The power electronics (1065) can comprise a Maximum Power Point Tracking (MPPT) circuitry. The MPPT can find and track the maximum power point from each energy conversion cell or a group of cells for the prevailing load conditions, which in turn can determine the optimal operating voltage for each cell or the group of cells. The power modules exemplified in FIG. 10A-FIG. 100, or a portion of it, can be located centrally. Merely by way of example, the power electronics (1065) can be on one printed circuit board.

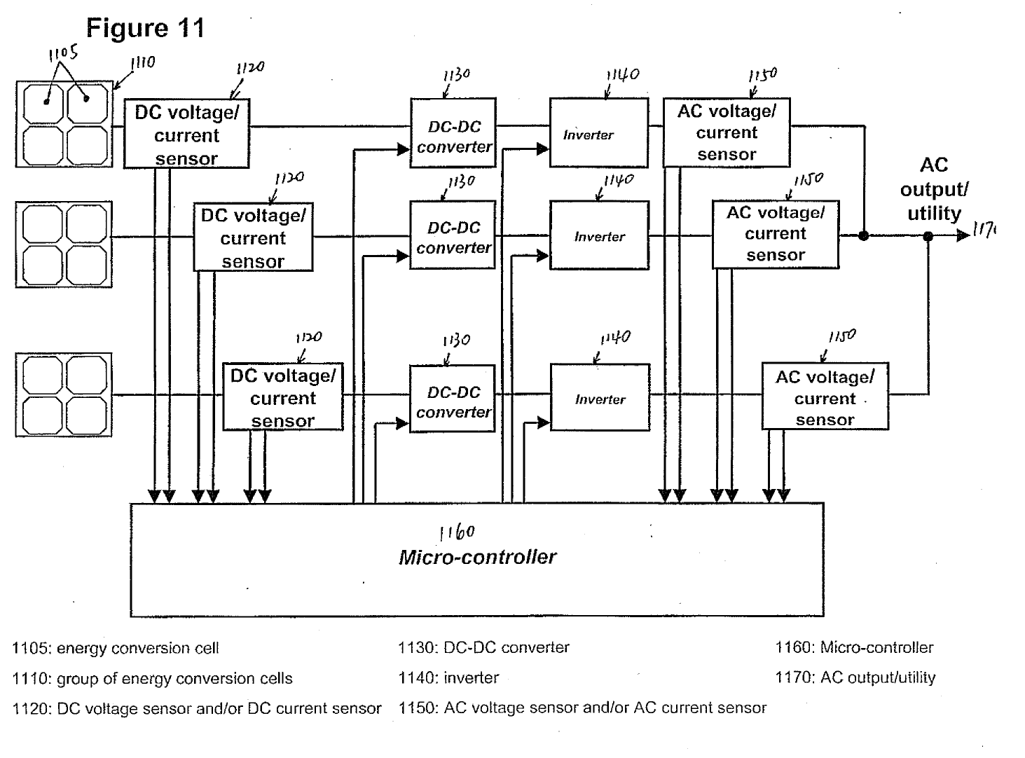

FIG. 11 shows a block diagram for an exemplary AC panel comprising a photovoltaic solar panel and a power module. The panel comprises multiple groups of energy conversion cells. Each group (1110) can comprise, without limitations, four energy conversion cells (1105) which can be electrically connected in series, in parallel, or in a combination thereof. It is understood that each group can comprise more or fewer than four energy conversion cells. Merely by way of example, each group can comprise one cell, or two cells, or three cells, or six cells, or more than six cells. The panel can comprise three groups. The panel can comprise more or fewer than three groups. Merely by way of example, the panel can comprise one group, two groups, or four groups, or more than four groups. Each group (1110) can be electrically connected to dedicated electronics, as exemplified in FIG. 10A. The dedicated electronics can comprise a DC voltage sensor and/or current sensor (1120), a DC-DC converter (1130), an inverter (1140), and an AC voltage sensor/current sensor (1150), or the like, or a combination thereof. The multiple groups within the panel can share one micro-controller (1160) as shown in FIG. 11. Each group can be electrically connected to dedicated electronics with its own micro-controller. Each group in FIG. 11 can function as described in FIG. 10A. If an individual group can generate DC of high voltage, the DC can be fed directly to an inverter without increasing the voltage by a DC-DC converter, as exemplified in FIG. 10C. The multiple groups (1110) with dedicated electronics can be electrically connected in parallel, as exemplified in FIG. 11, or in series, or in a combination thereof. Both MPPT and anti-islanding algorithms can be embedded in the memory of the micro-controller. The generated AC power can be output through 1170 to, such as, for example, a power grid or utility.

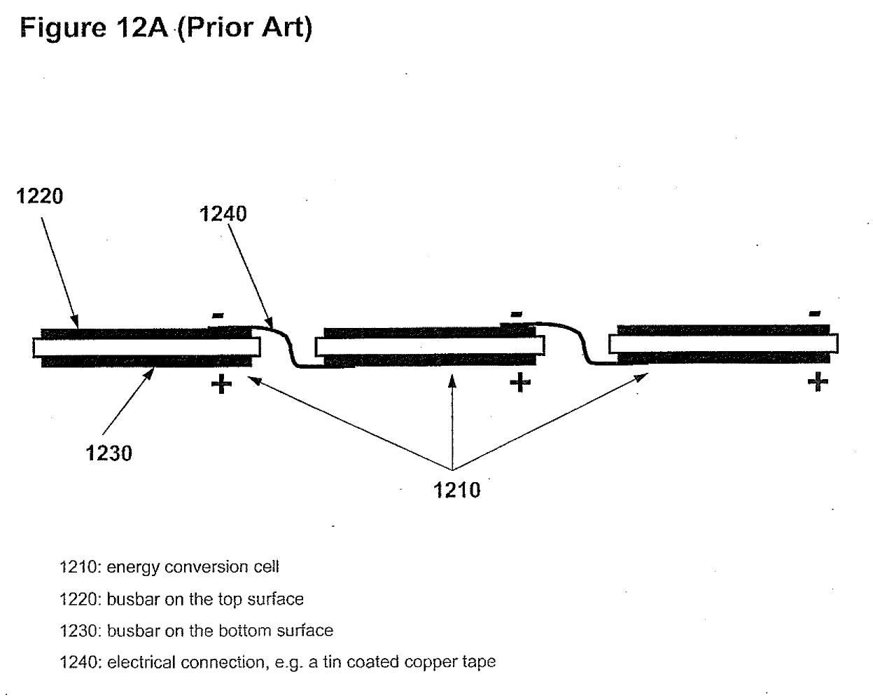

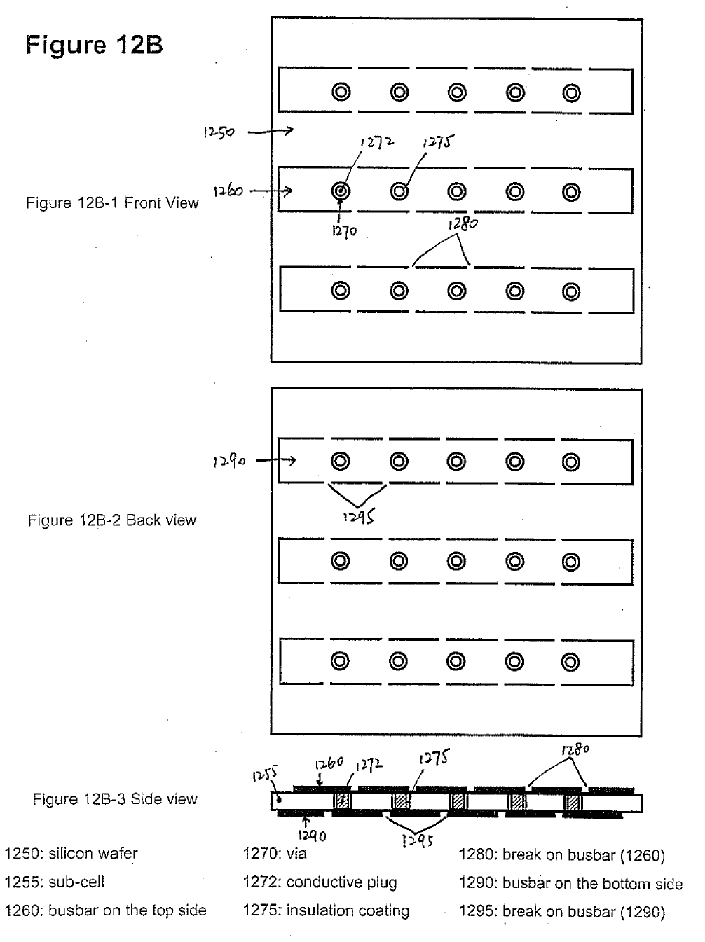

FIG. 12A shows an exemplary electrical connection of energy conversion cells (1210). Each energy conversion cell (1210) can include a busbar on the top surface (1220) which can be used as the negative polarity of the cell, and a busbar on the bottom side (1230) which can be used as the positive polarity of the cell. To form a serial connection, the negative polarity of a first cell can be connected to the positive polarity of a second cell through an electrical connection (1240), and the negative polarity of the second cell can be connected to the positive polarity of a third cell through an electrical connection (1240). The electrical connection (1240) can include a conductive tape, such as, for example, a tin coated copper tape. The electrical connection (1240) can include an insulation coating or edge isolation such that it does not create an undesired short circuit between the cells. It is well known to those skilled in the art that an energy conversion cell can have both its positive polarity and its negative polarity on the bottom side of the cell. The use of such cells in conjunction with the access matrix is also within the scope of the instant application.

A photovoltaic solar panel can comprise multiple energy conversion cells. At least one of the multiple energy conversion cells can be a high voltage energy conversion cell according to one aspect of the present invention. A high voltage cell can be made from a single cell by dividing it into a multitude of smaller sub-cells and connecting the sub-cells in series.

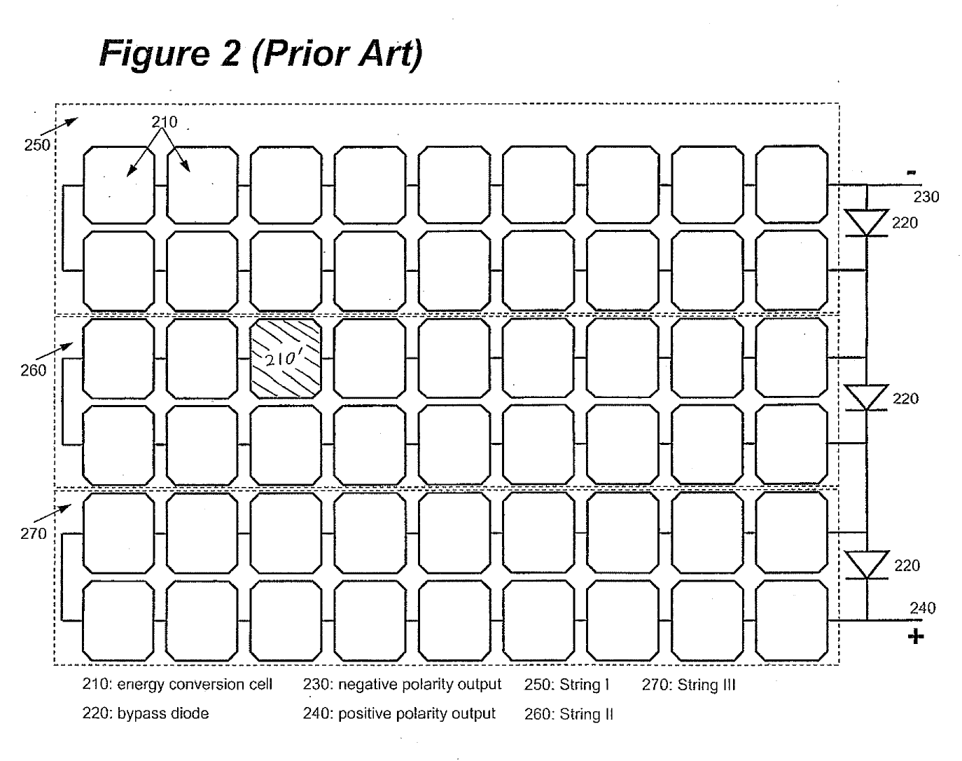

FIG. 12B-1 (front view), FIG. 12B-2 (back view) and FIG. 12B-3 (side view) show an exemplary high voltage cell comprising a silicon wafer (1250). It is understood that the mechanics described herein is applicable to other types of energy conversion cells which can comprise at least one material other than silicon. 1250 illustrates the silicon wafer; 1255 illustrates a sub-cell; 1260 (the dashed line, not to scale) illustrates a busbar on the top side of the silicon wafer (1250); 1270 (the large circle in the front view and in the back view) illustrates a via in the silicon wafer (1250) filled with a conductive plug (1272, the inner circle in the front view and in the back view) and an insulation coating (1275, the annulus between the big circle and the inner circle in the front view and in the back view); 1280 illustrates a break on the busbar on the top side of the silicon wafer (1250); 1290 illustrates a busbar on the bottom side of the silicon wafer (1250); and 1295 illustrates a break on the busbar, and any other conductive material if applicable, on the bottom side of the silicon wafer (1250). A sub-cell (1255) can be defined by breaking the busbar at the top side (1260) and the busbar (and any other conductive material if applicable) on the bottom side (1290) of the cell in stagger such that there is an overlap between the positive and negative polarities of adjacent sub-cells. A through wafer via (1270) filled with a conductive plug (1272) can make the electrical connection from the opposing polarities of the adjacent sub-sells as shown. The through wafer via (1270) is not electrically conductive except through the conductive plug within it. The through wafer via (1270) can be referred to as the via hereinafter. The conductive plug (1272) can comprise an insulation coating (1275) such that the conductive plug (1272) does not create a short circuit between the adjacent sub-cells. A through wafer via can be effectuated by, such as, for example, plasma etching, reactive ion etching, ion beam milling, or by laser drilling. The via can be filled with a suitable conductive material such as copper or tungsten. The high voltage cell can include multiple electrodes (not shown) on the top side of the cell which can be in electrical connection with the busbar (1260). The exemplary high voltage cell in FIG. 12B can comprise six sub-cells. The voltage of the DC generated by this cell can be the sum of that of the six sub-cells. Merely by way of example, if a 156 mm×156 mm energy conversion cell is divided into 6 sub-cells of 26 mm×156 mm, and if each sub-cell can generate a DC of about 0.6 volt, the DC voltage of about 6×0.6=3.6 V can be obtained from such a high voltage cell. Sixty such high voltage cells can be incorporated into a panel and obtain a DC voltage of about 60×3.6V=216V DC out of the panel. Such DC voltage can be suitable for an input to the embodiment shown in FIG. 10C.

A high voltage cell can include more or fewer than six sub-cells. A high voltage cell can include at least two sub-cells, or at least five sub-cells, or at least ten sub-cells, or at least twenty sub-cells. The total power from a high voltage cell remain substantially the same as an energy conversion cell which does not comprise sub-cells. A high voltage cell can generate high DC voltage, substantially in direct proportion of the number of sub-cells, while the current can be lowered by the same proportion. Since the current from a high voltage cell can be low, relatively small plugs (in cross section) can be used for the interconnections of the sub-cells. This can be advantageous in that the overlapping between the sub-cells can be at a minimum. Also the connection of one sub-cell to the adjacent sub-cell can be effectuated by one or more via/conductive plug structures in order to distribute the current to avoid local heating of the conductive plugs. A high voltage cell can be manufactured using a method similar to that for thin film technologies whereby the photovoltaic material (e.g., CdTe, CIGS, and amorphous silicon (a-Si) module) can be directly deposited on a substrate. The substrate can comprise at least one material selected from glass, metals, plastics or any other suitable material. The vias and/or the plugs can be made by appropriate etching and thin film deposition—similar to those used in IC manufacturing.

A photovoltaic solar panel can be manufactured as described herein. The panel can comprise a first sheet, energy conversion cells, an access matrix and a second sheet.

The first sheet can be where solar radiation strikes directly, or closer to the surface where solar radiation strikes than the second sheet. The first sheet can comprise a sheet of at least one material selected from glass, polyvinyl fluoride, polyester, ethylene vinyl acetate, Mylar, plastic, polyethylene, Kapton, polyimide, and polydinofluoride. The first sheet can comprise glass. The glass can comprise a smooth surface and/or a textured or prismatic with or without a matte finish such as the EcoGuard glass marketed by Guardian Industries Inc. A data sheet for such a glass is incorporated herein by reference. The smooth surface can be covered with a layer of broadband anti-reflection (AR) coating to enhance the transmission of the entire optical spectrum from the solar radiation by reducing reflection.

The energy conversion cells can comprise photovoltaic cells. The energy conversion cells can comprise high voltage photovoltaic cells. The energy conversion cells can be divided into groups. Each group can comprise at least one energy conversion cell. If a group comprises more than one energy conversion cell, the cells within a group can be electrically connected in series, in parallel, or in a combination thereof. The electrical connection between cells within a group can be established by various methods. Merely by way of example, each group can comprise four electrically connected (in series and/or in parallel) energy conversion cells, which can be soldered together via an electrically conductive tape. The electrically conductive tape can comprise, such as, for example, a tin coated copper tape or regular round copper wire. Merely by way of example, the electrically conductive tape can be from about 2 mm to about 4 mm wide, and about 100 micrometers thick. The electrically conductive tape can be coated with an alloy, such as, for example, tin or tin/silver alloy. It is understood that the methods to establish a serial electrical connection between cells within a group can be applied to establish a parallel electrical connection with minor and/or obvious modifications. The solder can be a lead free solder available from Kester (www.kester.com). The soldering flux can be a no-solids, no-clean flux such as #979T or #951 also available from Kester. The panel can further comprise soldering pads. The soldering pads can be on the bottom side of the cells, wherein the bottom side can refer to the side farther away from the first sheet than the opposing top side of the cell. The soldering pads can provide electrical access to the positive polarity and the negative polarity of each group for electrical connection outside the group, such as, for example, to the access matrix.

The access matrix can comprise a network of conductive tracks or wires. One end of a conductive track or wire can be connected to the soldering pads; and the other end can extend to a location outside the panel. Merely by way of example, the other end of a conductive track or wire can extend to a power module which can be located on an external surface of the second sheet, wherein the external surface can refer to a surface facing outward to the surroundings, not facing the inside of the panel.

The material of an access matrix comprising electrical conductors and/or dielectric body can be selected based on the considerations such as, for example, that the access matrix is compatible with the process of forming the hermetically sealed space, such as, for example, the thermo-compression lamination process, and the adjacent surfaces which can be in direct contact with the access matrix. An adjacent surface can comprise that of encapsulant (e.g., EVA), that of an energy conversion cell (e.g., silicon), that of the surface coating on an energy conversion cell (e.g. aluminum), that of the second sheet (e.g., PVF), or the like.

A method of making the access matrix can comprise placing electrically conductive tracks on a dielectric body. This process can be similar to a process of making a large printed circuit board. The electrically conductive tracks can comprise metal tracks. The dielectric body can comprise a separate layer than the second layer of encapsulant or the second sheet. The dielectric body can coincide with the second layer of encapsulant, or the second sheet. Merely by way of example, a metallic tape or ribbon with adhesive on one side can be used to basically “draw” the metal tracks on a dielectric body comprising Tedlar. The metal tracks can comprise dangling metal ends through which the metal tracks can be electrically connected to the energy conversion cells, for example, through soldering pads.

Another method of making the access matrix can comprise coating a dielectric body with an electrically conductive material; defining the electrically conductive tracks; and removing the electrically conductive material which are not the electrically conductive tracks. The dielectric body can comprise a separate layer than the second layer of encapsulant or the second sheet. The dielectric body can coincide with the second layer of encapsulant, or the second sheet. The electrically conductive material can comprise a metal (e.g., copper). This method can be of low cost and can be suitable for mass production.

Yet another method of making the access matrix can comprise keeping electrically conductive wires temporarily in a space; filling the space with a molten dielectric body material; and letting the dielectric body material solidify. The electrically conductive wires can comprise a metal, such as, for example, copper, aluminum, tin, tin coated copper, silver, steel, stainless steel, brass and bronze, or the like, or a combination thereof. The dielectric body material can comprise, such as, for example, resin, epoxy, or the like, or a combination thereof.

The panel can comprise at least one layer of encapsulant. The panel can comprise a first layer of encapsulant. The first layer of encapsulant can be between the first sheet and the energy conversion cells. The panel can comprise a second layer of encapsulant. The second layer of encapsulant can be between the energy conversion cells and the access matrix. The panel can comprise a third layer of encapsulant. The third layer of encapsulant can be between the access matrix and the second sheet. Any of the at least one layer of encapsulant can comprise, such as, EVA, or a dielectric material, or the like, or a combination thereof.

The second sheet can comprise a sheet of at least one material selected from glass, polyvinyl fluoride, polyester, ethylene vinyl acetate, Mylar, plastic, polyethylene, Kapton, polyimide, and polydinofluoride.

The power module can be located outside the panel. At least a portion of a power module can be housed in an enclosure. Such an enclosure can be located outside the panel. Merely by way of example, the enclosure can be mounted on an external surface of the second sheet of the panel. As used herein, the external surface refers to a surface facing outward to the surroundings, not facing the inside of the panel. The access matrix can provide electrical access to individual energy conversion cells or groups of cells for the power module. The power module can comprise at least one component selected from a bypass diode, a super barrier rectifier, a maximum peak power tracking (MPPT) circuit, a transformer, a DC-to-DC converter, a DC-to-AC inverter, a micro-controller, a microprocessor, an analog-to-digital converter, a digital-to-analogue converter, a temperature sensor, a humidity sensor, a frequency measurement device, and embedded algorithms, such as MPPT and/or anti-islanding algorithms. The power module can comprise a printed circuit board with at least one components described herein.

The method of manufacturing a photovoltaic solar panel can comprise placing a first sheet on a flat surface; placing the groups of energy conversion cells; placing the access matrix; forming electrical connection between the groups of the energy conversion cells and the access matrix; placing a second sheet; and forming a hermetically sealed space including the first sheet, the groups of energy conversion cells, the access matrix, and the second sheet. The hermetically sealed space can be formed by, such as, for example, lamination.

The lamination can be effectuated by heating all the layers described above to about 150 to about 180 degrees Celsius, and applying pressure for about 10 to about 15 minutes. The vacuum pressure can facilitate removing air from the panel in order to prevent air bubbles within the panel. A description regarding the lamination process can be found, for example, in El Amrani et al. (“Solar Module Fabrication”, International Journal of Photoenergy Volume 2007, Article ID 27610) which is incorporated herein by reference.

The first sheet can include a glass, and more preferably low-iron tempered glass. Said glass can be washed and dried before use.

A photovoltaic solar panel can comprise at least one layer of encapsulant. The method can include placing a first layer of encapsulant on the first sheet before placing the groups of energy conversion cells. The method can include placing a second layer of encapsulant on the groups of energy conversion cells before placing the access matrix. The method can include placing a third layer of encapsulant on the access matrix before placing the second sheet.

After forming the hermetically sealed space, the method can further include framing the panel.

The method can include forming electrical connection between the groups of energy conversion cells and a power module through the access matrix. At least a portion of dedicated electronics, e.g., a bypass diode, can be located within the panel, e.g., on the bottom side of an individual energy conversion cell. If the panel comprises at least a portion of the dedicated electronics located outside the panel, the method can include forming electrical connection between the groups of energy conversion cells and the dedicated electronics through the access matrix. The power module and the dedicated electronics can be mounted on the panel. Merely by way of example, the power module and the dedicated electronics can be housed in the same enclosure and be mounted on an external surface of the panel, wherein the enclosure does not block solar radiation incident on the panel.

A method of manufacturing a photovoltaic solar panel can be found in Amrani A. K. et al. (“Solar Module Fabrication”, International Journal of Photoenergy Volume 2007, Article ID 27610), which is incorporated herein by reference.

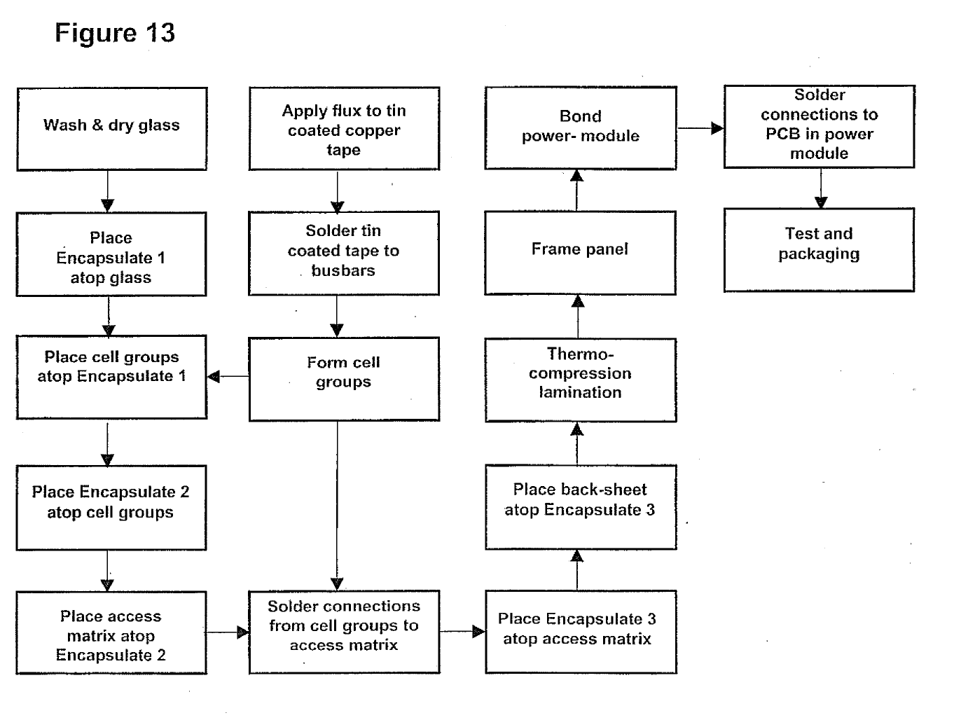

FIG. 13 shows an exemplary method of manufacturing a photovoltaic solar panel including washing and drying a sheet of glass, placing the sheet of glass on a flat surface; placing a first layer of encapsulant (Encapsulant 1) on the sheet of glass; placing the groups of energy conversion cells atop the first layer of encapsulant (Encapsulant 1), some of the energy conversion cells can be connected to each other in series, or in parallel, or in a combination thereof, to form groups; placing a second layer of encapsulant (Encapsulant 2) atop the groups of energy conversion cells; placing the access matrix atop the second layer of encapsulant (Encapsulant 2); forming electrical connection between the groups of the energy conversion cells and the access matrix by soldering; placing a third layer of encapsulant (Encapsulant 3); placing a second sheet (back sheet) atop the third layer of encapsulant (Encapsulant 3); and forming a hermetically sealed space including the sheet of glass, the first layer of encapsulant (Encapsulant 1), the groups of energy conversion cells, the second layer of encapsulant (Encapsulant 2), the access matrix, the third layer of encapsulant (Encapsulant 3); and the second sheet (back sheet) by thermo-compression lamination; framing the panel; bonding the power module; connecting the conductors out of the access matrix to the PCB by soldering, housing the printed circuit board (PCB) in the power module; and testing and packaging the panel. Forming the groups of cells can include applying flux to tin coated copper tape; and soldering tin coated tape to busbars. Merely by way of example, the bonding can be achieved using silicone.

A photovoltaic power generation system can comprise at least one, or at least two, or at least three, or at least five, or et least eight, or at least ten, or at least fifteen, or at least twenty, or at least twenty-five, or at least thirty, or at least forty, or at least fifty, or at eighty, or at least one hundred photovoltaic solar panel as described herein, wherein at least some of the photovoltaic solar panels can include power module. The combination of a photovoltaic solar panel with a power module can be referred to as an AC panel.

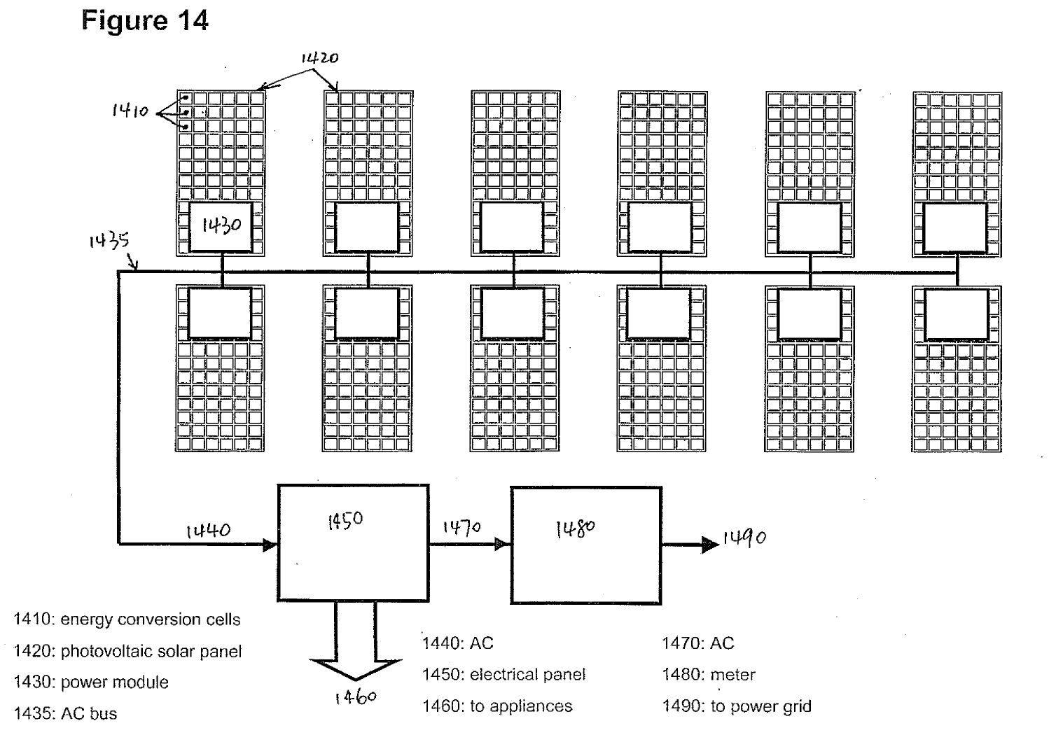

FIG. 14 shows a block diagram for an exemplary system with multiple AC panels (1420). Each AC panel (1420) can comprise multiple energy conversion cells (1410) and it can produce either single-phase, two-phase, split-phase, or three-phase AC power. Each AC Panel (1420) can deliver a voltage of 120V, 240V, or 208V, or the like. The energy conversion cells (1410) can be divided into groups. Each group can comprise at least one energy conversion cell (1410). Each group can include dedicated electronics. Each AC panel (1420) can comprise a power module (1430). Each panel (1420) can generate AC (1440). The multiple panels (1420) can be electrically connected to each other in parallel via an AC bus (1435). The AC bus (1435) can comprise at least two conductors, one for live and one for neutral. The AC bus (1435) can comprise, without any limitation, three conductors so that two can be allotted to two live power lines and one to neutral. In this situation the two live conductors can be at two AC voltages 180° out of phase with each other. For example, the two live conductors can each be at 120V, and the total voltage carried by the AC bus (1435) can be 240V. The AC bus (1435) can comprise, without any limitation, four conductors wherein two can be allotted to two live power lines, one can be allotted to neutral, and one can be allotted to AC ground. The AC bus (1435) can comprise, without any limitation, 5 conductors for a three-phase power transmission whereby three can be allotted to live lines each 120° out of phase with the neighboring line, one can be allotted to neutral, and one can be allotted to AC ground. Merely by way of example, for the three phases, the phase to neutral voltage can be about 110 to about 120V, and phase to phase voltage can be about 208V. It is understood that the values for the voltage referred to in the example are for illustration purposes only, and are not intended to limit the scope of the application. Different values for the voltages can be achieved with minor and/or obvious modifications to the AC panel, wherein the modification would be obvious to a person of ordinary skill in the relevant art. The AC bus (1435) can pass through the power module. Each AC panel can provide additional current to the AC bus (1435) in phase with the AC voltage. This way the more AC panels (1420) are connected to the AC bus (1435), the higher the current (1440) is flowing through the AC bus (1435). The AC (1440) can be fed to an electrical panel (1450). Through the electrical panel (1450), the AC (1470) can be sent to appliances (1460), and/or to a power grid (1490) through a meter (1480). Different groups within a panel may not connect to each other in series. A weak energy conversion cell which does not function normally, and/or is shaded, and/or comprises inferior/unmatched power generating capacity/property than the other cells within the panel may not affect the power generation of the other cells within the same panel. Merely by way of example, at least one energy conversion cell can comprise mono-crystalline silicon, and other cells can comprise polycrystalline silicon. Alternatively and merely by way of example, the access matrix can provide means to “mix and match” cells within the panel so that the current matching capability of cells can be alleviated. This can lead to a reduction in manufacturing cost in so far as pre-assembly the sorting of the cells is concerned. Furthermore, it is clear from the exemplary embodiment illustrated in FIG. 14 that the AC panels are not connected to each other series. If all panels are identical, they can contribute power equally to the AC bus (1435). If the panels are not identical, the imperfections of one panel may not affect the power generation capability of the neighboring panels.

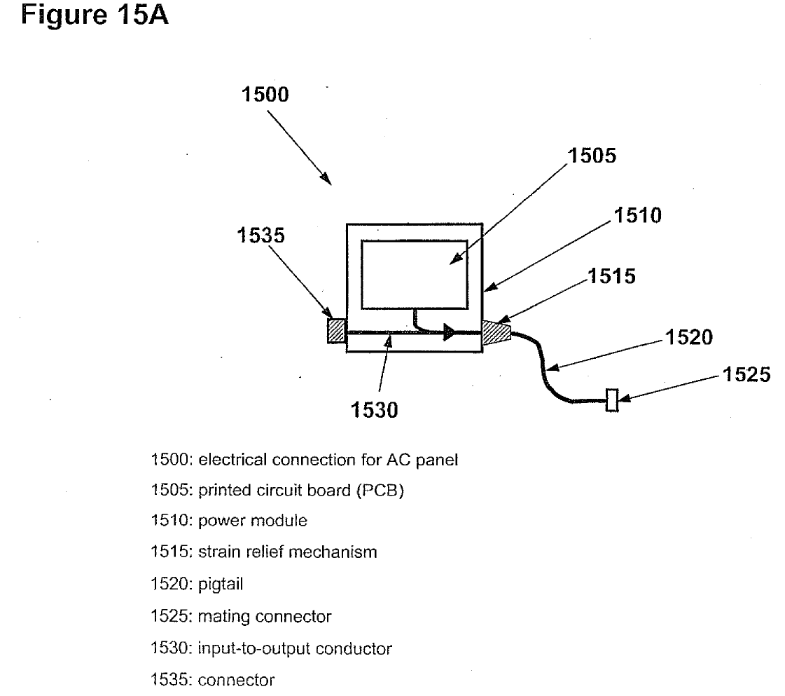

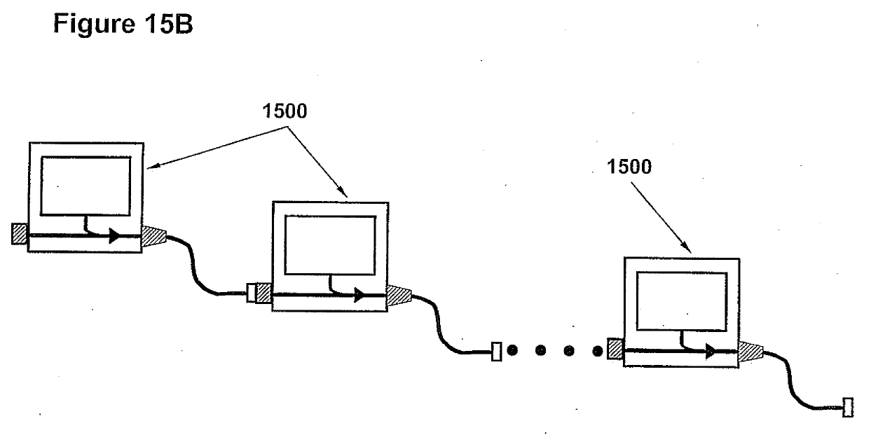

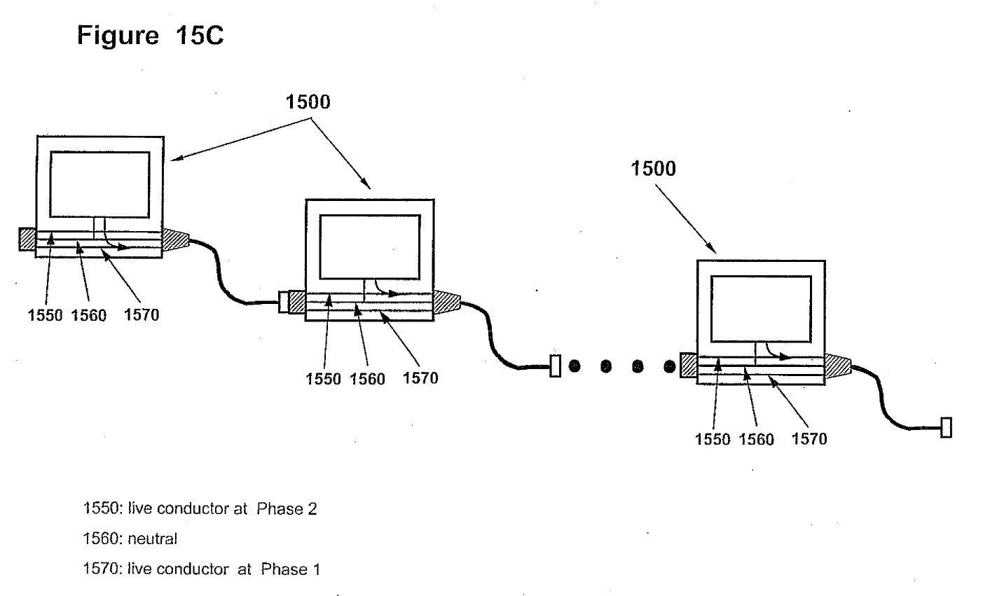

FIG. 15A shows an exemplary power module with electrical connection components (1500) through which an AC panel can output the AC generated by the panel. 1500 illustrates the power module (1510) of an AC panel (not shown) with electrical connection components as described below; 1505 illustrates a printed circuit board (PCB); 1510 illustrates a power module electrically connected to a photovoltaic panel (not shown); 1515 illustrates a strain relief mechanism; 1520 illustrates a pigtail; 1525 illustrates a mating connector; 1530 illustrates an input-to-output conductor; and 1535 illustrates a connector. The power module (1510) is mounted on the back of the panel (not shown) and can produce AC power. As used herein, back means that the external surface of the second sheet, or the external surface of the panel which is closer to the second sheet than to the first sheet. The power module (1510) can include a connector (1535) and a pigtail (1520) which can be connected to the power module through a strain relief mechanism (1515). 1515 can also provide sealing of the pigtail at the point where it enters the power module. 1515, can for example, comprise a cable gland such as those marketed by Hawke International. The length of the pigtail (1520) can be in the range of about 30 cm to about 3 meters, or a little longer than the width of a linear dimension of the panel so that when the panels are installed and placed next to each other the pigtail (1520) is long enough so that the mating connector (1525) of one panel can be connected to the connector (1535) of the next adjacent panel. The length of the pigtail (1520) can be from about 50% to about 300%, or from about 75% to about 200%, or from about 100% to about 150% of a linear dimension of the panel. At the end of the pigtail (1520) there can comprise a mating connector (1525). Inside the power module (1510) there can comprise an input-to-output conductor (1530) which may or may not be part of the PCB (1505). The power generated from the panel can be inverted to AC and fed to the input-to-output conductor (1530) and hence to the pigtail (1520) and then to the mating connector (1525).

FIG. 15B shows an exemplary connection of the AC panels through the power modules with electrical connection components (1500) comprising the connectors (1535) and mating connectors (1525). The electrical connection in FIG. 15B can be established through a multitude of connectors (1535), input-to-output conductors (1530), pigtails (1520), and mating connectors (1525). Merely by way of example, the power module (1510) illustrated in FIG. 15A can be designed, without limitation, to deliver 120V single-phase, or 240V split-phase. The power module (1510) can be configured to deliver two phases, wherein each phase is 180° out of phase to each other. The pigtail (1520) can comprise two live conductors (not shown) which can carry current 180° out of phase to each other. The two phases can be referred to as Phase-1 and Phase-2 for the purposes of this specification. The power module (1510) can output both Phase-1 and Phase-2. Merely by way of example, one live conductor can be at a voltage of about 120 V with a phase at Phase-1, the second conductor can be at a voltage of about 120 V with a phase at Phase-2, and the third conductor can be neutral. Depending on the power factor the AC on the two live conductors can be also about 180° out of phase with each other. It is further possible and it is within the scope of the instant application to provide such split-phase configuration to be used by appliances or be fed to the utility grid, if in a given power generation system (such as that exemplified in FIG. 14), with reference to FIG. 15A, the electrical connection components of the power module (1500) can comprise a 3-conductor pigtail (1520). If within a power generation system some panels produce an AC voltage at Phase-1 and other panels produce an AC voltage at Phase-2 and both sets of panels feed the same three-conductor AC bus the system power output can be about 240V. This way the split-phase configuration can be essentially synthesized in a distributed fashion to generate system output of about 240V without the need for a 240V power module. This split-phase configuration (without limiting the utility of a 240V power module which is also within the scope of the instant application), can be advantageous over a 240V power module because it can eliminate the use of a DC-to-DC converter in the power module of an AC panel, and thereby, increasing the efficiency of the power generation system by about 4% to about 15%.

FIG. 15C shows an exemplary connection of the AC panels through the power modules with electrical connection components (1500). FIG. 15C shows in more detail the breakdown of the input-to-output conductor (1530) of FIG. 15A. For a split-phase or 2-phase topology the input-to-output conductor (1530) consists of 3 separate conductors: the live conductor at Phase-1 (1570), the live conductor at Phase-2 (1550) and the neutral (1560). One AC panel can feed the live conductor (1570) at Phase-1 and the other can feed the live conductor (1550) at Phase-2. For the split-phase topology the phase difference between Phase-1 and Phase-2 can be about 180°. This way if an AC panel produces about 120V AC the overall voltage supplied can be about 240 V at the system level. Within the system, the number of panels generating power at Phase-1 and that of panels generating power at Phase-2 can be the same or different. The locations of the panels generating power at Phase-1 relative to those of the panels generating power at Phase-2 can be independent of the power generated by the panels and fed to the system. Whether or not a power module generates power at Phase-1 or Phase-2 can be controlled by switching the polarity of the DC input (1000) or AC output (1060) of FIG. 10A or FIG. 10B or 1170 of FIG. 11 in the power module. The same concept can be applied to a 3-phase signal wherein the input-to-output conductor (1530) of FIG. 15A can comprise three live conductors and one neutral, wherein the phase between three live conductors can be about 120°.

The skilled artisan will recognize the applicability of various configurations and features from different embodiments described herein. Similarly, the various configurations and features discussed above, as well as other known equivalents for each configuration or feature, can be mixed and matched by one of ordinary skill in this art to perform methods in accordance with principles described herein. It is to be understood that examples described are for illustration purposes only, and are not limiting as to the scope of the application.

All patents, patent applications, publications of patent applications, and other material, such as articles, books, specifications, publications, documents, things, and/or the like, referenced herein are hereby incorporated herein by this reference in their entirety for all purposes, excepting any prosecution file history associated with same, any of same that is inconsistent with or in conflict with the present document, or any of same that may have a limiting affect as to the broadest scope of the claims now or later associated with the present document. By way of example, should there be any inconsistency or conflict between the description, definition, and/or the use of a term associated with any of the incorporated material and that associated with the present document, the description, definition, and/or the use of the term in the present document shall prevail.

1. A photovoltaic solar panel comprising:
a first sheet and a second sheet adjacent to each other defining a space in between the two sheets, said first sheet being transparent to solar radiation incident on the panel;
energy conversion cells arranged in a plurality of groups in said space, each group comprising at least one energy conversion cell, the energy conversion cells distributed across a substantially two-dimensional plane between and adjacent to the two sheets; and
an access matrix in said space, said matrix comprising a plurality of electrical conductors that are electrically connected to the groups and that extend out of said space to provide electrical access to the groups from locations outside the panel, said space hermetically sealed to enclose said energy conversion cells therein.

2. The photovoltaic solar panel of claim 1 further comprising at least one layer of encapsulant in said space to provide said hermetical sealing for said energy conversion cells in the space, wherein encapsulant in said layer of encapsulant substantially fills the space between the two sheets, said energy conversion cells and the access matrix.

3. The photovoltaic solar panel of claim 1, wherein said energy conversion cells are arranged in at least two groups.

4. The photovoltaic solar panel of claim 1, wherein said first sheet or said second sheet comprises at least one material selected from glass, polyvinyl fluoride, polyester, ethylene vinyl acetate, Mylar, plastic, polyethylene, Kapton, polyimide, and polydinofluoride.

5. The photovoltaic solar panel of claim 1, wherein said access matrix comprises a dielectric layer.

6. The photovoltaic solar panel of claim 1, wherein said electrical conductors are located on the second sheet.

7. The photovoltaic solar panel of claim 5, wherein said electrical conductors are embedded within said dielectric layer.

8. The photovoltaic solar panel of claim 5, wherein said electrical conductors are bonded on at least one surface of said dielectric layer.

9. The photovoltaic solar panel of claim 8, wherein said electrical conductors comprise conductive tracks.

10. The photovoltaic solar panel of claim 1, wherein said electrical conductors comprise at least one material selected from copper, aluminum, tin, tin coated copper, silver, steel, stainless steel, brass and bronze.

11. The photovoltaic solar panel of claim 1 wherein said access matrix further comprises bypass diodes.

12. The photovoltaic solar panel of claim 11 wherein said bypass diodes comprise super barrier rectifiers.

13. The photovoltaic solar panel of claim 1 wherein said access matrix further comprises DC-to-DC converters.

14. A photovoltaic solar panel comprising:
a first sheet and a second sheet adjacent to each other defining a space in between the two sheets, said first sheet being transparent to solar radiation incident on the panel;
energy conversion cells arranged in a plurality of groups in said space, each group comprising at least one energy conversion cell, the energy conversion cells distributed across a substantially two-dimensional plane between and adjacent to the two sheets; and
an access matrix in said space, said matrix comprising a plurality of electrical conductors that are electrically connected to the groups and that extend out of said space
a power module wherein said access matrix provides electrical access to the groups by said power module, said space hermetically sealed to enclose said energy conversion cells therein.

15. The photovoltaic solar panel of claim 14, wherein said power module is hermetically sealed in a second space and permanently bonded to said photovoltaic solar panel, wherein the panel generates AC power.

16. The photovoltaic solar panel of claim 14, wherein said power module comprises at least one selected from bypass diode, a super barrier rectifier, a transformer, a DC-to-DC converter, a DC-to-AC inverter, a maximum peak power tracking circuitry.

17. The photovoltaic solar panel of claim 16, wherein said DC-to-AC inverter comprises anti-islanding, over current, undercurrent, over voltage, or under voltage provisions.

18. The photovoltaic solar panel of claim 14, wherein said power module houses at least one selected from a micro-controller, a microprocessor, an analog-to-digital converter, a digital-to-analogue converter, a temperature sensor, a humidity sensor, a frequency measurement device, diodes, embedded algorithms.

19. A photovoltaic power generation system comprising at least one photovoltaic solar panel of claim 1.

20. A method of manufacturing the solar panel of claim 1 comprising
providing the first sheet, the second sheet, energy conversion cells arranged in said plurality of groups, and the access matrix;
placing the first sheet;
placing the energy conversion cells distributed across the substantially two-dimensional plane over the first sheet;
placing the access matrix;
forming electrical connection between the access matrix and the energy conversion cells;
placing the second sheet over the access matrix; and
forming a hermetically sealed space comprising the first sheet, the second sheet, energy conversion cells, and the access matrix.
